(19) United States
(12) Patent Application Publication
(10) Pub. No.: US 2023/0185198 A1
(43) Pub. Date: Jun. 15, 2023

(54) Anisotropic Pattern Transfer Via Colloidal Lithography

(71) Applicant: The Trustees of the University of Pennsylvania, Philadelphia, PA (US)

(72) Inventors: Cherie R Kagan, Bala Cynwyd, PA (US); Christopher B. Murray, Philadelphia, PA (US); Austin Wesley Keller, Boise, ID (US)

(21) Appl. No.: 18/052,645

(22) Filed: Nov. 4, 2022

Related U.S. Application Data
(60) Provisional application No. 63/275,486, filed on Nov. 4, 2021.

(51) Int. Cl. G03F 7/20; H01L 21/033

(52) U.S. Cl. CPC G03F 7/2026; H01L 21/0332

(57) ABSTRACT

A patterning method, comprising: disposing a nanoparticle composition on a support material, the disposing being performed such that the nanoparticle composition defines a patterned region having an average inter-nanoparticle distance of less than about 5 nm; and selectively etching the support material so as to give rise to in the support material a plurality of arrayed structures substantially in register with the patterned region of the nanoparticle composition.

An article, comprising an article made according to the present disclosure.

A workpiece, comprising: an etchable support material; and a nanoparticle composition, the nanoparticle composition being disposed on the support material as a monolayer, the nanoparticle composition defining a patterned region having an average inter-nanoparticle distance of less than about 5 nm, and nanoparticles of the nanoparticle composition having ligands disposed thereon.

An article, comprising: a substrate, the substrate having formed therein a plurality of structures arranged arrayed periodically, the structures defining an average inter-structure spacing of less than about 5 nm.

### CROSS-REFERENCE TO RELATED APPLICATIONS

The present application claims priority to and the benefit of U.S. patent application No. 63/275,486, “Anisotropic Pattern Transfer Via Colloidal Lithography” (filed Nov. 4, 2021), the entirety of which application is incorporated herein by reference for any and all purposes.

### TECHNICAL FIELD

The present disclosure relates to the field of nanoscale patterning and to the field of lithography.

### BACKGROUND

The semiconductor industry has been the most significant driving force for developing nanoscale technology. Although challenging, the frontier of nanofabrication capabilities has led to the commercialization of patterning features near 10 nm, and there are ongoing efforts to realize patterning below 5 nm. The ability to pattern features or their spacings at such a small scale would not only extend Moore's law for integrated circuit technology and memory devices but would also permit fundamental research of exciting chemical and physical phenomena. Such pursuits would enable the development of plasmonic metasurfaces for sensing applications, optoelectronic devices, and quantum technologies.

Since its inception, the semiconductor industry has relied heavily on photolithography to achieve high-throughput patterning over large areas. Demand for smaller features has pushed the resolution limits of this technique to the point where commercial photolithography can routinely pattern features below 20 nm. However, this approach requires a combination of several sophisticated techniques that employ many complex process steps to be performed by expensive state-of-the-art equipment. The recent commercialization of extreme ultraviolet (EUV) lithography has allowed for successful patterning of even smaller features, below 10 nm in lateral dimension. At the same time, it is uncertain whether EUV lithography can reliably pattern features below 5 nm. Furthermore, the high cost of EUV systems is prohibitive for research purposes that require prototyping or for small-volume production markets.

Researchers have developed and implemented several other specialized fabrication methods for patterning at small length scales, including direct-write methods such as focused ion beam lithography, aberration-corrected electron beam lithography, and scanning probe lithography, and other approaches such as nanoimprint lithography and post-trimming methods. Each of these techniques has strengths and limitations.

For example, direct-write methods offer precision and arbitrary pattern design but generally suffer from low throughput. Nanoimprint lithography provides higher throughput but generally does not offer as high a resolution or precision in overlay registration as direct-write methods. Most implementations of nanoimprint lithography are better-suited for features larger than 10 nm, and efforts toward sub-10 nm patterning are limited by low feature density. Top-down lithographic approaches alone are ill-suited to pattern below 5 nm.

In contrast to purely top-down approaches, self-assembly methods such as directed self-assembly (DSA) of block copolymers and colloidal lithography have been widely implemented to integrate bottom-up patterning with top-down pattern transfer. Block copolymer DSA leverages nanoscale phase segregation, where one phase is then selectively removed to form a mask of various pattern morphologies. Most patterns using this approach have demonstrated a critical dimension greater than 20 nm, and pattern transfer demonstrations of 2D morphologies, such as hexagonal or square motifs, have not been demonstrated in the sub-20 nm regime. Efforts toward smaller feature sizes have only been realized in 1D patterns. Controlled morphology with high resolution resulting from block copolymer DSA typically requires pre-defined topographic or chemical patterning, increasing the process complexity. A drawback for pattern transfer with this approach is that polymer structures generally suffer from low etch selectivity and require sequential infiltration synthesis to enhance etch resistance or the use of a secondary hard mask. Overall, pattern transfer using the block copolymer DSA approach struggles to realize sub-5 nm patterning and tends to have considerable line edge roughness at small length scales.

Colloidal lithography offers a different approach by using particles as building blocks assembled to establish a pattern, where each particle serves as a discrete mask for subsequent deposition or etching. To date, most demonstrations of pattern transfer using colloidal lithography have shown features that are larger than 50 nm. The few examples that have explored the sub-50 nm regime have utilized close-packed spherical nanocrystals (NCs), leading to isotropic features with hexagonal ordering. There has yet to be a high-fidelity pattern transfer demonstration of discrete, anisotropic features below 40 nm with a high feature density and a sub-5 nm critical dimension. To date, the inventors are not aware of any work that has been able to simultaneously combine the following three aspects for pattern transfer which we successfully demonstrate: 1) a sub-5 nm critical dimension, 2) a 2D pattern with high feature density, and 3) discrete, anisotropic features.

### SUMMARY

In meeting the described long-felt needs, the present disclosure provides, inter alia, the use of monodisperse, anisotropic NC building blocks (e.g., GdF₃ which have a rhombic plate morphology and a dendrimer ligand species) to effect formation of nanoscale features. (Although GdF₃ is used herein as an example, it should be understood that the disclosed technology is not limited to using GdF_{3.}) The disclosed process marks the first use of a rare-earth fluoride NC material for pattern transfer in which the inorganic NC cores are spaced by a dendrimer ligand. GdF₃ exhibits a high etch selectivity for both fluorine-based and chlorine-based dry etch chemistries, a useful feature for successful pattern transfer. Additionally, the G2 dendrimer molecule enables sufficient colloidal stability and spacing upon NC assembly. Furthermore, one can utilize other rare-earth chalcogenide material systems which have a variety of anisotropic morphologies. Control over the material, shape, size, and monodispersity of the NC building blocks offers flexibility in the exploration of nanoscale patterning and pattern transfer into a variety of substrate materials.

In one aspect, the present disclosure provides a patterning method, comprising: disposing a nanoparticle composition on a support material, the disposing being performed such that the nanoparticle composition defines a patterned region having an average inter-nanoparticle distance of less than about 5 nm; and selectively etching the support material so as to give rise to in the support material a plurality of arrayed structures substantially in register with the patterned region of the nanoparticle composition.

Also provided is an article, comprising an article made according to the present disclosure, e.g., according to any one of Aspects 1-10.

Further provided is a workpiece, comprising: an etchable support material; and a nanoparticle composition, the nanoparticle composition being disposed on the support material as a monolayer, the nanoparticle composition defining a patterned region having an average inter-nanoparticle distance of less than about 5 nm, and nanoparticles of the nanoparticle composition having ligands disposed thereon.

Additionally disclosed is an article, comprising: a substrate, the substrate having formed therein a plurality of structures arranged arrayed periodically, the structures defining an average inter-structure spacing of less than about 5 nm.

### BRIEF DESCRIPTION OF THE DRAWINGS

The file of this patent or application contains at least one drawing/photograph executed in color. Copies of this patent or patent application publication with color drawing(s)/photograph(s) will be provided by the Office upon request and payment of the necessary fee.

In the drawings, which are not necessarily drawn to scale, like numerals can describe similar components in different views. Like numerals having different letter suffixes can represent different instances of similar components. The drawings illustrate generally, by way of example, but not by way of limitation, various aspects discussed in the present document. In the drawings:

FIGS. 1A-1C provide: FIG. 1A Schematic overview of the anisotropic pattern transfer process. [1] A ˜7 nm film of SiO₂ is grown on a Si wafer using a dry thermal oxidation process and is functionalized with a silane molecule to make the surface hydrophobic. [2] The NC monolayer assembly is transferred from a liquid-air interface to the substrate surface. [3] An O₂ descum process is used to remove the ligands and any residual organic material, then the thin SiO₂ layer is etched in regions between the NCs using a short CF₄/O₂ ICP RIE. [4] The underlying Si substrate is then etched using Cl₂/Ar ICP RIE to transfer the anisotropic pattern. [5] The NC mask layer is removed via liftoff of the underlying SiO₂ layer using a 10% HF wet etch. The magnified view of the patterned substrate shows lateral dimensions A, B, C, and D which are set by the NC mask size, spacing s set by the interparticle spacing of the NC assembly, and etch depth d which is determined by the dry etch conditions. FIG. 1B SEM image of the GdF₃-D NC monolayer assembly on a SiO₂/Si substrate (step 2). FIG. 1C SEM image of the patterned Si substrate after NC mask and SiO₂ removal (step 5). Scale bars are 100 nm.

FIGS. 2A-2D provides FIG. 2A cross-sectional schematic of the disclosed liquid-air interfacial self-assembly technique and subsequent film transfer onto a substrate via the Langmuir-Schaefer method. [1] The desired volume of the NC dispersion is drop-cast onto the liquid subphase. [2] The well is covered with a glass slide to decrease the evaporation rate and allow the self-assembly process to occur. [3] The glass slide is removed when the NC film is completely dry, then the substrate surface is carefully lowered toward the NC film until contact is made. [4] The substrate is translated vertically upward, any excess subphase is wicked away, and the sample is dried under vacuum. FIG. 2B TEM, FIG. 2C SEM, and FIG. 2D AFM (phase contrast) images of a well-ordered monolayer assembly of GdF₃-D NCs on a substrate using the assembly method described in 2A. Scale bars are 20 nm.

FIGS. 3A-3C provide a characterization of pattern transfer and the critical dimension s using 2D assemblies of discrete, anisotropic GdF₃-D NC masks. FIG. 3A Characterization of GdF₃-D monolayer assembly. The histogram shows consistency in s regardless of substrate material. (b-c) Characterization of pattern transfer into FIG. 3B SiNₓ and 3C SiO₂ via ICP RIE. (Left) Representative TEM image. (Middle) Histogram of edge-to-edge spacing s using measurements from TEM characterization of 500 interparticle spacings. (Right) Representative SEM image. The GdF₃ NCs are still present in FIG. 3B and FIG. 3C after the dry etch process. The SEM images in FIG. 3B and FIG. 3C show patter transfer into the respective bulk substrate. Scale bars are 10 nm for the TEM images and 50 nm for the SEM images.

FIGS. 4A-4D provide characterization of the complete pattern transfer process on bulk Si as described in FIGS. 1A-1C. FIG. 4A Schematic cross-sections and corresponding top-down SEM images after process steps 2-5. Step 5 is post-NC liftoff, leaving behind only the patterned Si substrate. Scale bars are 20 nm. FIG. 4B Characterization after mask removal (step 5) over a large area. Bright-field optical image of the sample surface (center). The surrounding SEM images correspond to locations 1-4 indicated on the optical image. The scale bar is 10 um in the optical image and 100 nm in the SEM images. FIG. 4C AFM height characterization of the patterned surface after steps 4 and 5. Scale bars are 20 nm. FIG. 4D Cross-sectional SEM image of the patterned Si surface after mask removal showing the feature height d˜50 nm. The scale bar is 50 nm.

FIG. 5 provides a cross-sectional schematic of the complete pattern transfer process as described in FIG. 1(a).

FIGS. 6A-6D provide a characterization of the anisotropic morphology of exemplary GdF₃ NC building blocks. FIG. 6A Atomistic model of the rhombic plate geometry of GdF₃ with diagonal axes A and B, axes C and D normal to the parallel sides, and thickness, t. FIG. 6B TEM image and FIG. 6C corresponding histogram of measurements A, B, C, and D from TEM characterization of the GdF₃ NCs. FIG. 6D SAXS experimental data and corresponding atomistic x-ray simulation which corroborates the NC morphology and provides thickness t=2.2 nm.

FIGS. 7A-7C provide FIG. 7A Experimental SAXS results comparing GdF₃-OA and GdF₃-D. The sample with oleic acid shows distinct diffraction peaks. The first peak is located at q=1.04 nm⁻¹ (indicated by the arrow) which corresponds to a systematic center-to-center spacing of 6.0 nm, resulting from lamellar stacking of the GdF₃ NCs in solution when oleic acid is the ligand. This is not the case for the sample with the dendrimer ligand, indicating better colloidal stability with D. FIG. 7B Schematic showing the preferential lamellar stacking morphology with GdF₃-OA NCs in solution where p=6.0 nm. Since the thickness of each GdF₃ is t=2.2 nm, the spacing between NCs due to the steric repulsion from the ligands is s=3.8 nm. If we consider the ligand length as L=s/2, then L=1.9 nm, which is consistent for oleic acid. FIG. 7C Chemical drawing of the second-generation dendrimer molecule with a phosphonic acid head group used for ligand exchange.

FIG. 8 provides representative low magnification TEM images with highlighted grain boundaries. The grains have an edge length of approximately 1-2 μm. Scale bars are 500 nm.

FIG. 9 provides characterization of the anisotropic feature dimensions A, B, C, and D before and after ICP RIE for the SiO₂ membrane. The mask dimensions are of the original NC assembly (lighter shade) and post-pattern transfer (darker shade). The etch process erodes the sharp corners of the NC mask to produce a more rounded corner profile, causing a decrease in dimensions A and B. The parallel sides of the NC mask normal to directions C and D slightly increase post-etch, most likely due to sidewall passivation using the CF₄-based etch chemistry.

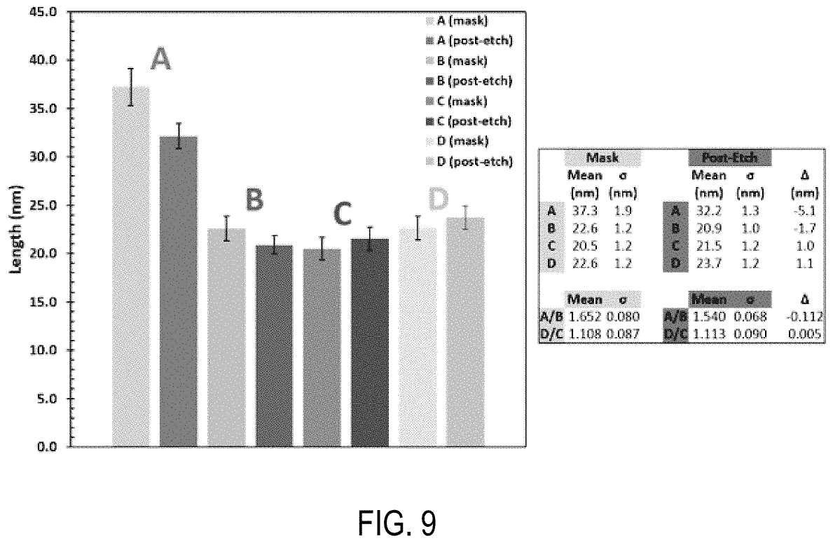

FIG. 10 provides a depiction of the pattern transfer morphology established by the GdF₃ NC mask pattern. Dimensions A and B are the rhombus diagonals, and dimensions C and D represent the distance normal to the parallel sides. The measurement of linear feature density is performed along directions C and D as noted by pitches p_{C} and p_{D}. The pillar edge-to-edge spacing s is the critical dimension, and d is the feature height post-pattern transfer and mask removal. The TEM image is a post-etching result on an SiO₂ membrane with NCs still present. The scale bar is 20 nm.

FIGS. 11A-11C provide photographs of an example setup for solution-based silanization of substrates. A covered glass dish with the silane solution and sample is placed in a bell jar along with an environmental monitor that measures temperature, relative humidity, and the corresponding dew point. The bell jar is covered, and a dry air line is placed to the jar inlet from the fume hood, the flow of which can be manually tuned using a flow gauge to adjust the RH. FIG. 11A provides an overview of the setup. FIG. 11B provides a closer view of the interior of the covered system. FIG. 11C provides an uncovered view of a sample with the silane solution being stirred.

FIG. 12 provides SEM images of the pattern transfer process for steps 2-5 on a bulk Si substrate for different silanization treatments. The SiO₂ surface was treated with MPTS, FPTS, MTS, or TOS. [2] NC assembly pattern after film transfer, [3] SiO₂ open using CF₄/O₂ ICP RIE, [4] Si substrate etch using Cl₂/Ar ICP RIE, and [5] SiO₂/NC liftoff to reveal only the patterned Si surface. All scale bars are 50 nm. MPTS: (3 mercaptopropyl) trimethoxysilane; FPTS: (3,3,3-trifluoropropyl)trichlorosilane); MTS: methyltrimethoxysilane; TOS: triethoxyoctylsilane.

FIGS. 13A-13B provide example photoluminescence spectra. FIG. 13A Multilayer film of GdF₃ NCs dropcast onto a substrate which shows two distinct photoluminescence peaks near green (˜545 nm) and red (˜655 nm) wavelengths, characteristic of the Er³⁺ and Yb³⁺ dopants in the GdF₃ NCs. FIG. 13B PL spectra of a monolayer assembly of GdF₃ NCs on a substrate (blue) which shows the characteristic green and red PL peaks, and post-liftoff of the NC mask (green) after pattern transfer, which shows no peaks, indicating successful NC removal.

FIG. 14 provides AFM height image and corresponding line scan of the patterned silicon surface after process step 5. Although the surface topography is clear, the measured height is only ˜2.9 nm between the anisotropic structures for the respective line scan. This measured height is not reflective of the true feature height, but rather is an inherent limitation of the AFM characterization method due to the sample morphology. Despite using a special carbon spike probe, the probe cannot reach the full depth of the trench due to the extremely narrow space (<5 nm) between the silicon pillars. A larger spacing permits the probe to reach further into the etched areas as seen in the interstitial sites.

FIGS. 15A-15B provide sample morphology used for DOE-1. FIG. 15A Optical image of the sample post-exposure and develop of the resist which consists of microscale line-space patterns down to 2 μm. FIG. 15B Cross-sectional schematic of the material stack used to fabricate the microscale line-space patterns in silicon. A photoresist is used to pattern a layer of SiO₂ which serves as the etch mask for pattern transfer into Si.

FIGS. 16A-16B provide marginal means plots for each of the four input parameters (ICP Power, HF Power, Ar Content, and Pressure) for the outputs of FIG. 16A etch depth and FIG. 16B surface roughness (R_{q}), based on the data presented in Table 9.

FIG. 17 provides a summary of the Pareto analysis performed for the data from DOE-1 which shows the coefficient, or relative significance of the influence, from each input parameter on the respective output measurement—etch depth and surface roughness.

FIGS. 18A-18D provide a nanoimprint lithography (NIL) and pattern transfer used to investigate DOE-2. FIG. 18A SEM image of the master Si hard stamp used for imprinting. FIG. 18B Cross-sectional schematic of the NIL process and pattern transfer into Si. FIG. 18C AFM height image of the patterned Si sample 2.1 after pattern transfer, liftoff, and descum. FIG. 18D Higher magnification AFM height image of sample 2.1 indicating an example measurement on a single trench. The corresponding trench profile on the right shows measurements of the etch profile.

FIG. 19 provides AFM height images of samples 2.1-2.9 used to investigate DOE-2. These images are of the patterned Si surface after pattern transfer, liftoff, and O₂ descum.

FIGS. 20A-20B provide marginal means plots for each of the four input parameters (ICP Power, HF Power, Ar Content, and Pressure) for the outputs of 20A etch depth and 20B sidewall slope for DOE-2.

FIGS. 21A-21B provide marginal means plots for each of the four input parameters (ICP Power, HF Power, Ar Content, and Pressure) for the outputs of FIG. 21A surface roughness (R_{q}) and FIG. 21B V_{dc} for DOE-2.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints (e.g., “between 2 grams and 10 grams, and all the intermediate values includes 2 grams, 10 grams, and all intermediate values”). The endpoints of the ranges and any values disclosed herein are not limited to the precise range or value; they are sufficiently imprecise to include values approximating these ranges and/or values. All ranges are combinable.

As used herein, approximating language can be applied to modify any quantitative representation that can vary without resulting in a change in the basic function to which it is related. Accordingly, a value modified by a term or terms, such as “about” and “substantially,” may not be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

Example Disclosure

The ability to pattern a desired material below 5 nm opens many research opportunities ranging from basic science to technological applications. However, current nanofabrication methods are ill-suited for sub-5 nm patterning and pattern transfer. Here, we demonstrate the use of colloidal lithography to transfer an anisotropic pattern of discrete features into substrates with a critical dimension below 5 nm. The assembly of monodisperse, anisotropic nanocrystals (NCs) with a rhombic-plate morphology spaced by dendrimer ligands results in a well-ordered monolayer that serves as a 2D anisotropic hard mask pattern. This pattern is transferred into the underlying substrate using dry etching followed by removal of the NC mask layer.

We exemplify this approach by fabricating an array of pillars with a rhombic cross-section and an edge-to-edge spacing of 4.4 nm±1.1 nm. The presented fabrication approach enables wider access to patterning materials at the deep nanoscale by implementing innovative processes into well-established fabrication methods while minimizing the overall process complexity.

We demonstrate 2D patterning and subsequent pattern transfer of high-density, anisotropic features with a critical dimension below 5 nm via NC colloidal lithography using only five major process steps which can be performed in a standard fabrication facility. Our approach integrates bottom-up NC synthesis and self-assembly with top-down dry etching to realize high-fidelity pattern transfer into the desired substrate.

The bottom-up patterning approach is illustrated with monodisperse, anisotropic GdF₃ NCs as exemplary building blocks. The NCs have a faceted rhombic-plate morphology and are functionalized with a dendrimer ligand (G2). The NCs are assembled at the liquid-air interface into a well-ordered monolayer to establish the pattern, where each NC serves as a discrete hard etch mask. This pattern is then transferred into the underlying substrate using inductively coupled plasma (ICP) reactive ion etching (RIE), after which the NC mask layer is selectively removed to realize a 2D patterned substrate surface of rhombic pillars (32 nm×21 nm) that are 50 nm tall with a sub-5 nm spacing. The method demonstrated in this work enables wider access to patterning at and below 5 nm.

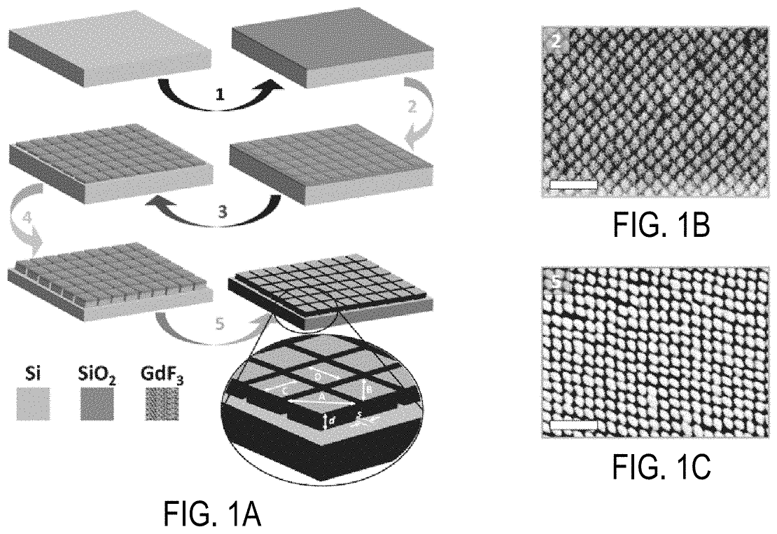

A schematic overview of the fabrication process is shown in FIG. 1A. Using a mild, dry thermal oxidation process, we grow a 7 nm SiO₂ layer on a Si substrate and perform a silanization treatment to make the surface hydrophobic (step 1). A well-ordered monolayer of monodisperse, anisotropic rhombic-plate NCs is formed via self-assembly at the liquid-air interface. This ordered NC monolayer is transferred to the substrate surface using the Langmuir-Schaefer method (step 2), as shown by the representative SEM image in FIG. 1B. After a brief O₂ plasma descum process, we use ICP RIE with CF₄/O₂ chemistry to etch through the thin SiO₂ layer (step 3), then etch into the underlying Si substrate using Cl₂/Ar ICP RIE (step 4). We finally remove the NC monolayer by a wet etch liftoff of the underlying SiO₂ layer using hydrofluoric acid (step 5), leaving behind the patterned Si substrate, as shown in FIG. 1C. The thin SiO₂ film serves as a sacrificial liftoff layer for NC mask removal and can act as a secondary etch mask when using Cl₂-based chemistry.

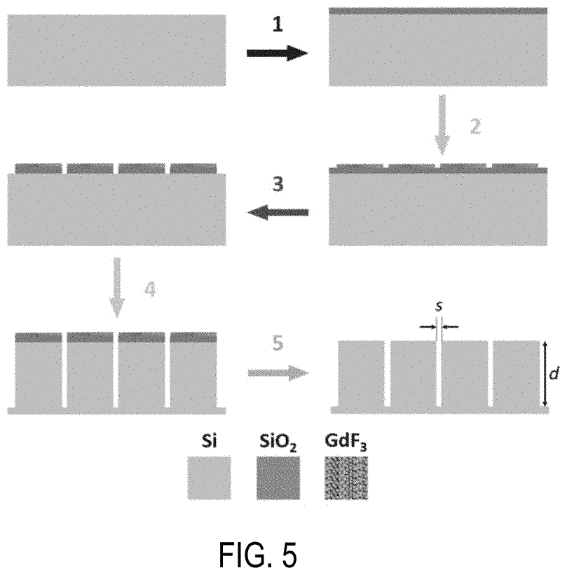

FIG. 5 depicts a schematic cross-sectional view of this pattern transfer process. The magnified view in FIG. 1A shows the patterned features with long axis A and shorter axis B, widths C and D between the parallel sides, edge-to-edge spacing s, and pillar height d. The specific dry-etch chemistry and process conditions determine the final feature height.

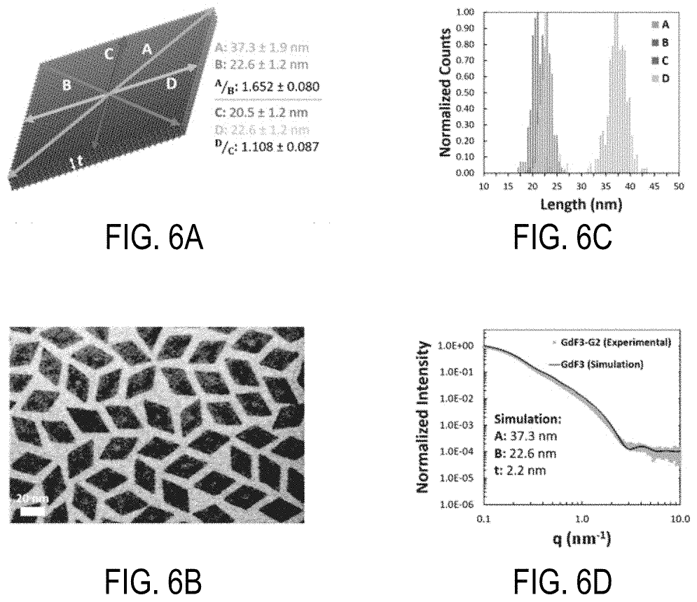

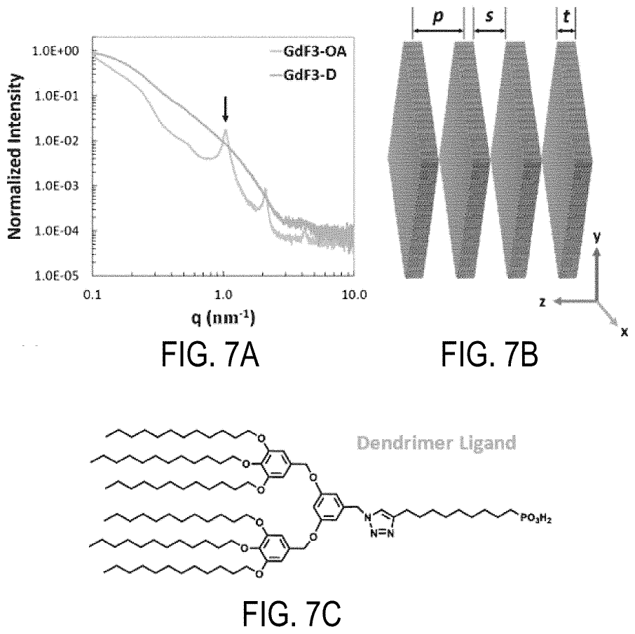

We synthesize monodisperse GdF₃ rhombic plates doped with Er³⁺ and Yb³⁺ and functionalized with oleate ligands (GdF₃-OA) to serve as building blocks. The plate thickness (t) is 2.2 nm. There are four characteristic lateral dimensions. The diagonal axis dimensions A and B are 37.3±1.9 nm and 22.6±1.2 nm, respectively. The dimensions normal to the parallel sides, C and D, are 20.5±1.2 nm and 22.6±1.2 nm, respectively. FIG. 6 provides a detailed characterization of the anisotropic GdF₃ NC morphology. We replace native oleates with a bulkier dendrimer ligand (GdF₃-D) through a solution-based ligand exchange procedure. The dendrimer provides improved colloidal stability to prevent NCs from stacking in solution (described by FIG. 7) to yield NC assemblies with improved order, and the dendrimer sets the interparticle spacing.

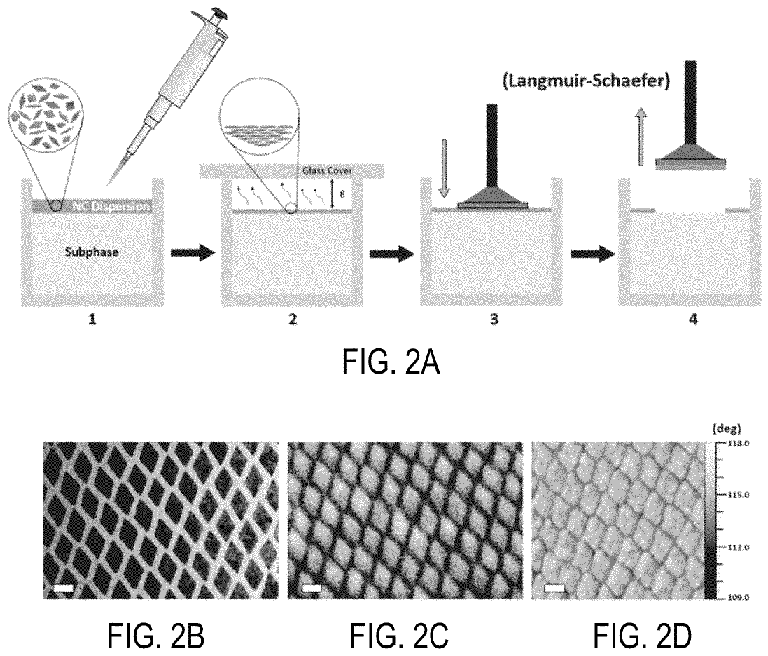

A prerequisite for high-quality pattern transfer is the organization of highly-ordered NC assemblies. We achieve this ordering through self-assembly at the liquid-air interface, as shown in FIG. 2A. The self-assembly process begins with filling a 2.25×2.25×1.5 cm³ Teflon well with 3.2 mL of ethylene glycol (EG). The GdF₃-D NC dispersion in toluene is then drop-cast onto the EG surface using 80 μL at a 0.2 mg/mL concentration. The well is quickly covered with a glass slide to decrease the solvent evaporation rate and allow the self-assembly process to occur. After solvent evaporation, the glass slide is removed, and the substrate is carefully lowered face-down to the surface of the liquid subphase until contact is made. The substrate is lifted vertically, any excess liquid subphase is removed by wicking with a clean wipe, and the sample is dried under vacuum at 50° C. The backside of the substrate is held by a suction device to keep the substrate surface parallel to the liquid-air interface. Environmental conditions such as temperature and humidity affect the solvent evaporation rate and therefore influence the assembly process. Faster drying typically results in multilayer films and can lead to poor film uniformity and degraded local order. We perform NC assembly in an air-filled glovebox, which controls relative humidity to tune the dew point to ˜10° C.

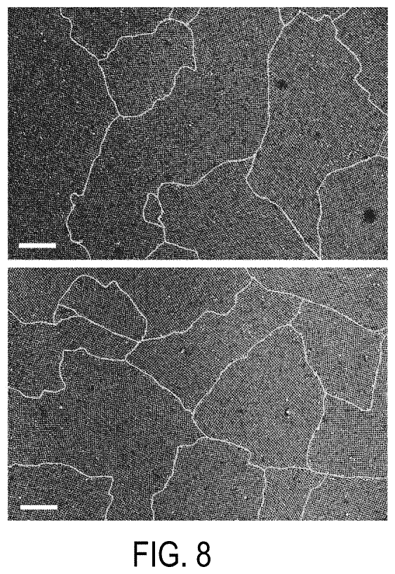

Representative TEM, SEM, and AFM images of the resulting anisotropic NC mask pattern prepared by self-assembly are shown in FIGS. 2B-2D, respectively. The NCs are assembled parallel to the substrate with commensurate ordering of the facets. The anisotropic NC pattern exhibits uniformity in feature size, shape, orientation, and spacing due to the narrow dispersity of the GdF₃-D NCs. The self-assembly process naturally results in ordered NC grains separated by grain boundaries. The anisotropic NCs are oriented in the same direction within a grain, but the orientation varies between different grains across the substrate. FIG. 8 shows typical grain sizes which have an edge length of approximately 1-2 pm. Within an ordered domain, the edge-to-edge spacing (s) between the NCs is set by the organic ligand shell. One can considers to be the critical dimension (CD) of the pattern since the space between the inorganic NC masks will be etched during pattern transfer.

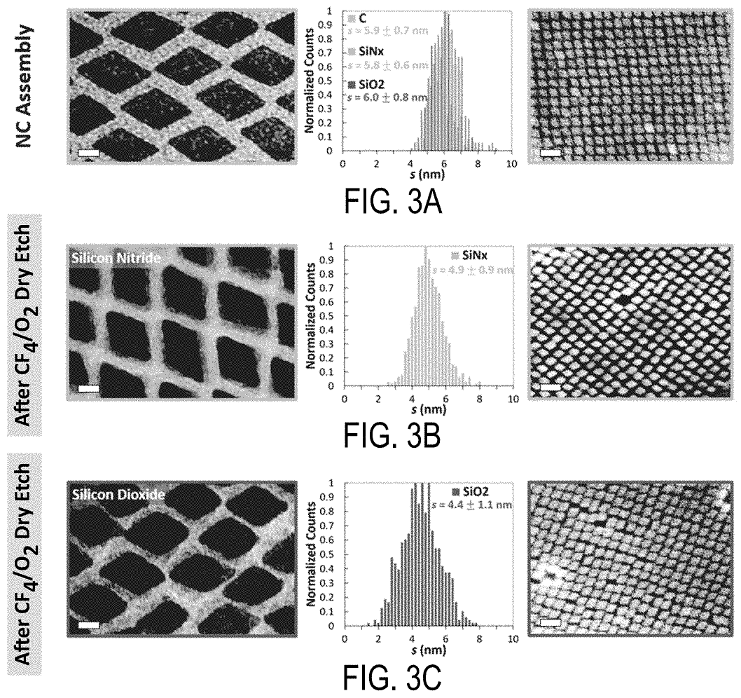

FIG. 3 provides an analysis of s before and after pattern transfer. The left column of FIG. 3 shows a representative TEM image with a corresponding histogram of the edge-to-edge spacing s in the middle column, and a representative SEM image in the right column. While TEM offers higher resolution over both SEM and AFM, the low penetration depth of the electrons inherently makes top-down characterization on a bulk substrate infeasible.

To enable higher-resolution characterization using TEM, we perform the patterning and pattern transfer steps on thin membranes of SiNₓ and SiO₂, two commonly used materials in device fabrication. FIG. 3A shows characterization of the assembled NC mask pattern. As demonstrated by testing on carbon, SiNₓ, and SiO₂ membranes, transferring the NC pattern to a different substrate material does not affect the spacing s. The dendrimer ligand yields a CD of s=5.9±0.7 nm, s=5.8±0.6 nm, and s=6.0±0.8 nm for the carbon, SiNₓ, and SiO₂ membrane, respectively.

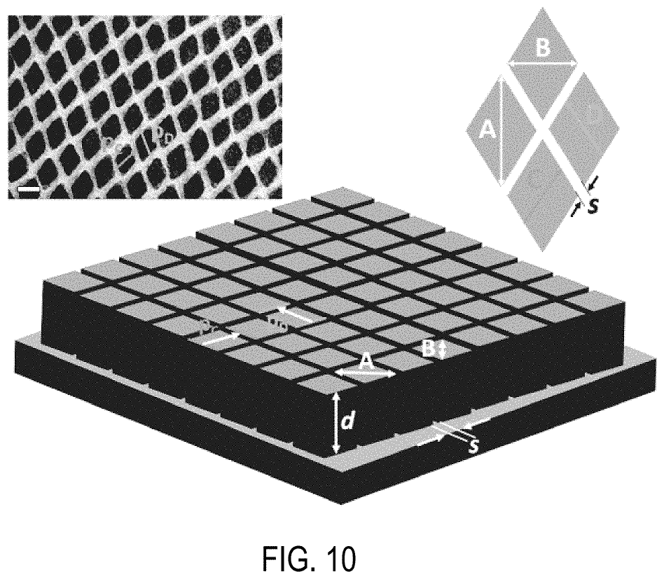

The SEM images in the right panel of FIG. 3B-3C show the pattern transfer result performed on bulk SiNₓ and SiO₂, demonstrating high-quality pattern transfer over a length scale of hundreds of nanometers with a high feature density. The linear feature density is defined as FD=alp, where a is the feature size and p is the feature pitch. 1D line-space patterns have been fabricated with FD>0.5 for larger features, but not for sub-5 nm features. Most demonstrations of sub-5 nm pattern transfer have only realized isolated features or demonstrated FD<0.1.^{27,70} If we consider the critical dimension s as the feature size a, the channel feature density in directions C and D are ˜0.17 and ˜0.16, respectively, for the SiO₂ substrate. A more detailed description of the feature pitch is provided by FIG. 10. The corresponding feature density of the rhombic pillars in directions C and D are ˜0.83 and ˜0.84, respectively, for the SiO₂ substrate.

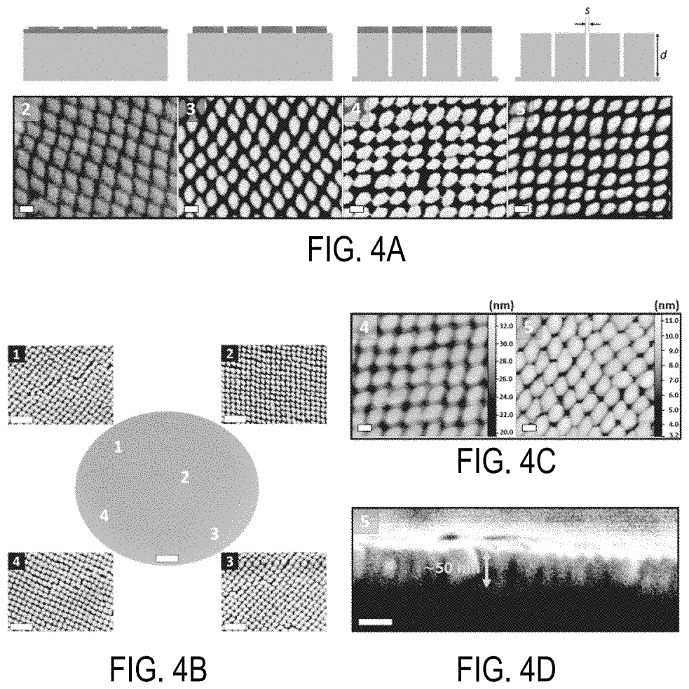

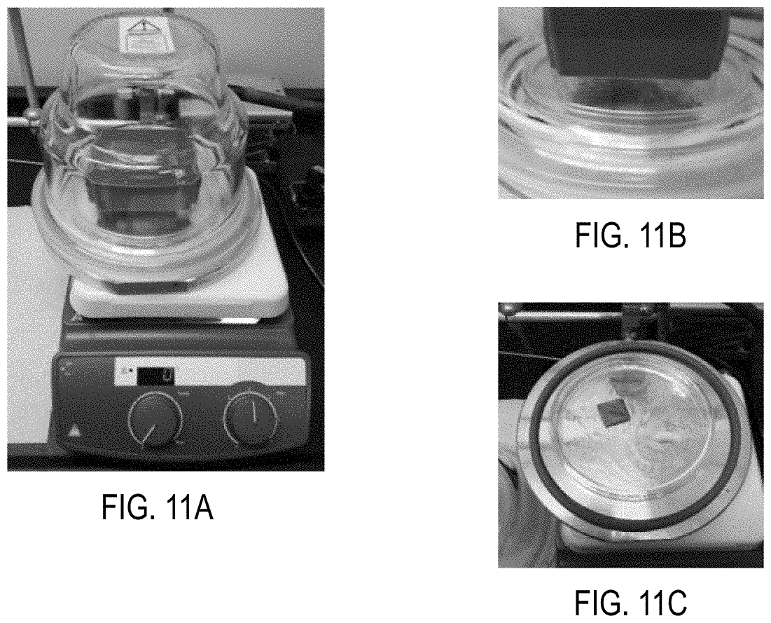

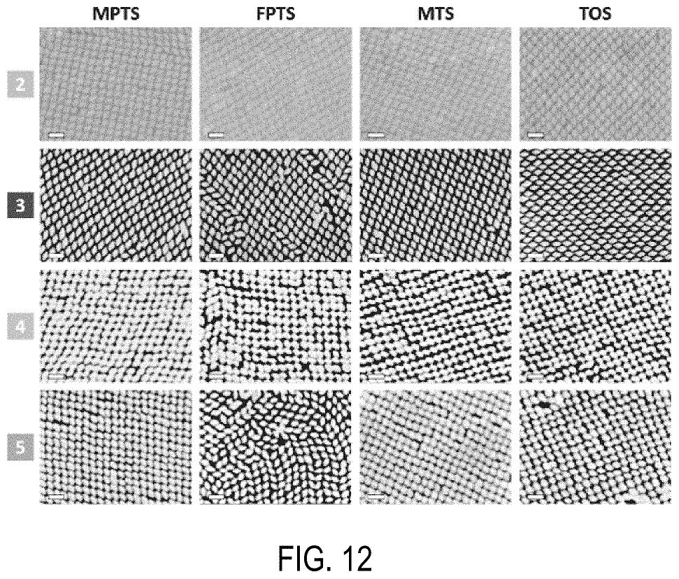

Returning to fabrication on a bulk SiO₂/Si substrate, we note the hydrophilic nature of SiO₂ can present challenges with film transfer of the hydrophobic NC assembly from the liquid-air interface to the substrate surface. To promote successful film transfer and improve the adhesion of the NC monolayer to the SiO₂/Si substrate, we functionalize the SiO₂ surface with a hydrophobic silane (e.g., methyltrimethoxysilane), as described by FIG. 11. We note that the complete process flow is compatible with the use of several other silanes at this step, as demonstrated in FIG. 12. The complete patterning and pattern transfer process for anisotropic features with a critical dimension below 5 nm on a bulk SiO₂/Si substrate is demonstrated in FIG. 4A, where the numbers and corresponding cross-sectional schematics refer to the steps described in FIG. 1A. After the NC film is transferred to the substrate, the ligands are removed through an O₂ descum process. The anisotropic pattern set by well-ordered NC assembly (step 2) is first transferred into the SiO₂ layer using CF₄/O₂ chemistry (step 3), then into the bulk Si substrate using Cl₂/Ar chemistry (step 4), followed by NC mask liftoff (step 5). The specific dry-etch chemistry and process conditions determine the final feature height, d.

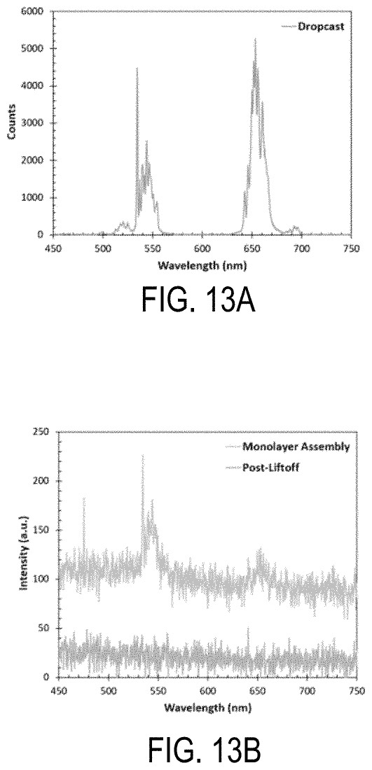

To confirm the efficacy of our liftoff process in step 5, we collect upconversion photoluminescence spectra before and after liftoff, as shown in FIG. 13. Before liftoff, we observe peaks around 545 nm, and 655 nm, which are characteristic of the Yb³⁺, Er³⁺-doped GdF₃ NCs. These peaks are no longer detectable post-liftoff, confirming the successful removal of the NCs. FIG. 4B shows characterization of the cleanly patterned Si substrate surface after mask liftoff. The central bright-field optical image highlights the uniformity of the substrate surface which is patterned across a centimeter length scale. The surrounding SEM images in FIG. 4B correspond to the locations 1-4 indicated on the optical image.

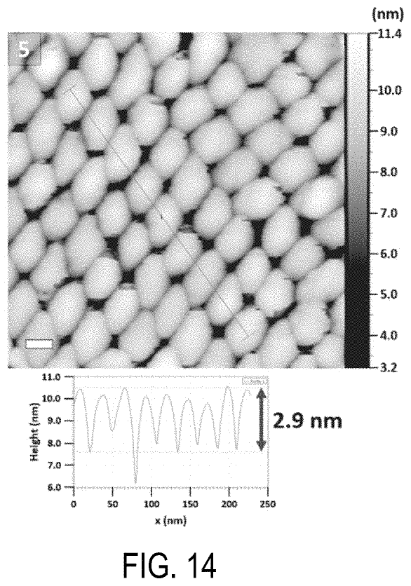

To characterize the patterned surface beyond top-down SEM images, FIG. 4C shows AFM height data which reveal the surface topography after process steps 4 and 5. FIG. 14 provides an AFM line scan measurement after NC mask removal. While AFM provides high-resolution height measurements and the visualization of the sample topography, the sample morphology makes it inherently challenging to analyze the true pillar height. Since the feature spacing is less than 5 nm, even the sharpest AFM probes available cannot reach the bottom of the etched channels, highlighting the success of our approach for pattern transfer at the deep nanoscale. For a clearer view, FIG. 4D provides a cross-sectional SEM image after mask removal (step 5), which reveals d 50 nm. The resulting feature height is sensitive to process conditions and can be increased or decreased by adjusting the Cl₂/Ar ICP RIE conditions such as etch time and high frequency (HF) power.

In summary, we demonstrate pattern transfer of anisotropic features into substrates with a critical dimension below 5 nm by integrating bottom-up and top-down strategies. To demonstrate this technology, a self-assembled, well-ordered monolayer of monodisperse GdF₃ NCs with an anisotropic rhombic-plate morphology functionalized with dendrimer ligands was used to set the anisotropic hard mask pattern on a desired substrate material. This pattern was transferred into the underlying substrate using conventional dry etching with ICP RIE, followed by selective removal of the NC mask, thereby providing a demonstration of 2D pattern transfer of densely packed anisotropic features with a critical dimension below 5 nm.

Additional Disclosure

The growth of the thin oxide (or other) layer that underlies the NCs can have a two-fold functionality. One purpose of the oxide in this work is to act as a sacrificial liftoff layer for NC mask removal in the last process step (step 5 in FIG. 1A. An additional role of the oxide is to serve as a secondary hard etch mask for pattern transfer using Cl₂-based etching. This is of value, as this fabrication approach can thus be applied to other NC morphologies and material systems, including those that may not have as high an etch selectivity as GdF₃. In the case the original NC mask material is eroded during dry etching, the SiO₂ (or other) layer can increase etch selectivity for Cl₂-based etching and enable fabrication of higher aspect ratio features. This design choice enables a rich choice of sub-5 nm patterning morphologies via NC colloidal lithography. In this way, one can etch the nanoparticle (e.g., NC) composition that provides an initial pattern and also form a further mask (e.g., SiO₂ or other material) of sorts. The further mask can in turn support pattern transfer during further etching of the substrate on which the hard mask is superposed.

The anisotropic morphology of the GdF₃ NCs means the orientation of the NC can influence establishing a regular pattern. Aside from environmental conditions, choice of solvent(s), subphase, and time, a significant factor that influences NC assembly quality and morphology is the chosen organic ligand. The surface ligands serve to stabilize the NCs in solution and are the dominant influence over interparticle interactions in solution and during the self-assembly process. Prior work has shown the subphase can influence anisotropic NC orientation, and how the ligand choice and design can influence the resulting orientation and morphology of NCs upon self-assembly. FIG. 7 highlights the role of the dendrimer ligand in maintaining NC stability in solution. When oleic acid is the ligand, small-angle x-ray scattering (SAXS) results indicate the GdF₃ NCs tend to form oriented lamellar stacks even in solution. This preferential ordering before assembly can significantly influence the resulting morphology and quality of the NC assembly using the self-assembly approach implemented. In general, using the dendrimer enables more robust assembly results with the NCs oriented parallel to the liquid-air interface.

The demonstrated fabrication approach enables wider access to sub-5 nm pattern transfer. Additionally, this fabrication strategy offers further opportunities to leverage the extensive library of NC mask materials and morphologies to generate arbitrarily complex patterns.

Control over the material, shape, size, and monodispersity of the NC building block offer flexibility in the exploration of nanoscale patterning and pattern transfer. Furthermore, this pattern transfer approach can be extended to other substrate materials including, metals, less traditional semiconductors, magnetic materials, dielectric materials, amorphous materials, and quantum materials like doped diamond or 2D materials. The presented fabrication platform provides wider access to patterning at the deep nanoscale by implementing innovative processes into well-established fabrication methods while minimizing the overall process complexity. The techniques developed and demonstrated by this work impact several sectors by enabling single-digit nanofabrication of various morphologies on a variety of technologically relevant substrate materials for use in integrated circuits, memory devices, optoelectronics, plasmonic metasurfaces for chemical/biological sensing applications, and quantum devices. As but one example, the disclosed colloidal lithography approach can be used to fabricate uniform, high-density arrays of structures that are small enough to isolate single defects in doped materials, thereby providing a significant step forward for quantum electronic and photonic devices.

Experimental Methods

Nanocrystal Synthesis and Purification

GdF₃:Er³⁺, Yb³⁺

Materials: All chemicals were used as purchased with no further purification. Gadolinium(III) oxide (99.9%), Erbium(III) oxide (99.9%), Ytterbium(III) oxide (99.9%), lithium fluoride (99.98%), oleic acid (technical grade, 90%), and 1-octadecene (technical grade, 90%) were purchased from Sigma Aldrich. Trifluoroacetic acid (99.5%) was purchased from Alpha Aesar. Ethylene glycol (99.5%) was purchased from Sigma Aldrich.

Precursor Preparation: Rare earth trifluoroacetate precursors are prepared based on the method presented in the literature, using the respective rare earth oxide and trifluoroacetic acid. 10 g of the rare earth oxide, 50 mL of trifluoroacetic acid, and 50 mL of DI H₂O are mixed in a 250 mL round bottom flask. The flask is placed into an oil bath held at 80° C. and the mixture is refluxed for 3 hrs. The solution is dried using a rotary evaporator for 30-60 min. The material is then placed under vacuum until it is completely dry and is then ground into a fine powder for storage. The precursor is assumed to be in the hexahydrate form and is designated as RE(CF₃COO)₃ for the synthesis.

Nanocrystal Synthesis: The GdF₃ NCs are synthesized by mixing together 0.980 g Gd(CF₃COO)₃, 0.0257 g Er(CF₃COO)₃, 0.259 g Yb(CF₃COO)₃, 0.216 g LiF, 30 mL oleic acid, and 30 mL 1-octadecene together in a custom-made 125 mL conical three-neck flask. The flask is connected to a Schlenk line using a bump trap and placed under vacuum to degas the solution at 125° C. for 3 hrs. After degassing, the reaction is placed under continuous N₂ flow and heated to 290° C. at a rate of ˜10° C./min. During ramping, the septum is removed from one neck at ˜250° C. for 10 s, then recapped. The reaction is continued to ramp to 290° C. and held at temperature for 4 hrs, then cooled to room temperature by removing the heating mantle with the flask remaining attached to the Schlenk line under N₂ flow.

Nanocrystal Purification: The reaction material is purified using four distinct washing steps followed by a size selection process. In the first washing step the reaction material is separated into three 50 mL centrifuge tubes (˜20 mL in each). 15 mL of hexane is added to the reaction flask to rinse out any remaining reaction material, and 5 mL is added to each of the three centrifuge tubes. 25 mL of ethanol is added and mixed into each tube (1:1 solvent:antisolvent ratio) and the contents are centrifuged at 6500×g for 2 min. The supernatant is decanted and discarded. In step two the precipitate in one tube is redispersed using 5 mL of hexane, then this same solution is mixed with the remaining two tubes to concentrate all material in a single tube. 2 mL of hexane is used to do a final rinse of each of the three tubes and added to the concentrated product solution. 18 mL of ethanol is added to the tube which is then centrifuged at 3500×g for 1 minute, followed by decanting and discarding the supernatant.

In step three the precipitate is redispersed in 5 mL of hexane, then 10 mL of ethanol is added followed by centrifuging at 3500×g for 1 minute and discarding the supernatant. The precipitated material is dried under vacuum. In the final wash step, the precipitate is redispersed in 10 mL of hexane. No antisolvent is added, and the material is centrifuged at 3500×g for 1 minute. The supernatant is retained (this is the NC product) and the precipitate (mostly lithium salt) is discarded. The resulting GdF₃ rhombic plate NCs are coated with oleic acid ligands and are stored in hexane or toluene.

Size Selective Precipitation: The GdF₃-OA NC dispersion is brought to a concentration of ˜15 mg/mL in hexane and placed into a centrifuge tube that is constantly and gently stirred. Dehydrated ethanol is slowly added in a dropwise manner until the solution starts to become cloudy. For a 5 mL sample, this usually occurs when ˜1 mL of antisolvent has been added. The sample is centrifuged at 8000×g for 5 min and the supernatant is poured into another clean centrifuge tube. The precipitated NCs are dried under vacuum and redispersed in hexane. This process is repeated on the remaining NC dispersion (supernatant) for several steps with progressively increasing ethanol content until all NC material has been extracted. The first size selection step will have the largest NCs, and the last step will have the smallest. Inspection of each size selection separation is performed using TEM, and samples of the same or very similar size can be combined. The largest and smallest NCs of the original size distribution are removed, yielding a more monodisperse sample, necessary for high quality NC assembly.

Dendrimer Ligand Exchange: Dendrimer synthesis and ligand exchange are described in previously published literature. The dendrimer ligand exchange is performed by placing the NCs in the presence of an excessive amount of the dendrimer molecule in solution under mild heating, and then washing in three steps to remove excess, unbound ligand molecules. A 1 mL NC dispersion of GdF₃-OA is prepared to a concentration of 10 mg/mL in hexane. 10 mg of the solidified dendrimer is dissolved in 2 mL of chloroform to make the ligand solution. This dendrimer solution is then mixed with the NC dispersion in a glass vial which is capped and left to stir at 50° C. overnight (>12 hrs). For washing, the contents (3 mL) are poured into a centrifuge tube. 1 mL of hexane is used to rinse out the vial and added to the centrifuge to bring the total sample volume to 4 mL. 8 mL of ethanol is added as an anti-solvent (2:1 anti-solvent:sample) and the sample is centrifuged at 8,000×g for 3 min.

The supernatant is discarded to waste and the precipitate is redispersed in 2 mL of hexane using vortex mixing and sonication for 2 min. The sample is washed a second time by adding 4 mL of methanol (2:1 anti-solvent:sample) and centrifuging at 6,000×g for 5 min. The sample is redispersed the same as before in 2 mL of hexane and then washed by repeating the prior step using methanol one more time. After the third washing step the precipitate is redispersed in 1 mL of toluene and kept at a concentration of 10 mg/mL for storage.

Nanocrystal Self-Assembly

Liquid-Air Interfacial Self-Assembly: LAISA is conducted using a Teflon well with a size of 2.25 cm×2.25 cm×1.00 cm. 3.2 mL of ethylene glycol (EG) is placed into the well to serve as the liquid subphase. The GdF₃-D NC dispersion is brought to a concentration of 0.2 mg/mL in toluene, and 80 μL was carefully dropcast onto the surface of the EG. The well is fully covered with a glass slide overnight (>12 hrs). The environmental conditions are very influential on the evaporation rate of the solvent and the assembly quality. We perform the assembly in an air-filled glove box so we can control the relative humidity to adjust the dew point. NC assembly is performed with the dew point near ˜10° C. (typically a temperature of 22.5° C. and relative humidity of 45%). After leaving covered overnight, the glass slide is carefully removed, and the film is left to sit uncovered for at least 15 min to ensure the NC film is completely dry and stable. The NC monolayer is then carefully transferred to the desired substrate using the Langmuir-Schaefer method. For TEM characterization, the film is transferred to a 3 mm copper mesh carbon support grid, a 50 nm thick silicon nitride membrane, or a 100 nm thick silicon dioxide membrane purchased from Electron Microscopy Sciences. For pattern transfer on a bulk substrate, the NC film is transferred to a test grade (100) silicon coupon approximately 1 cm×1 cm in size. See below for more details on surface preparation of the silicon substrate. After film transfer, excess EG was removed from the surface by wicking with a wipe, and the substrates were dried under vacuum while being heated to ˜50° C. for at least 3 hrs to remove residual EG.

Silicon Substrate Surface Preparation: A 1 cm×1 cm sample is cleaved from a (100) test grade silicon wafer purchased from NOVA Electronic Materials. Samples are cleaned using bath sonication at high power in acetone, ethanol, and isopropyl alcohol, sequentially, each for 5 min. For experiments with a thin film of SiO₂ which serves as a lift-off layer, a clean silicon wafer is subjected to a dry thermal oxidation process. The wafer is placed into a tube furnace under pure N₂ flow, and the temperature is ramped to 900° C. At this process temperature, continuous flow of dry air is introduced into the chamber and the wafer is left to oxidize for 45 min. The oxidation is quenched by purging the chamber with pure N₂ flow and the wafer is left to cool.

The surface of samples with the 7 nm film of SiO₂ are naturally hydrophilic, which leads to dewetting and poor film transfer of the NC monolayer assembly. To make the surface hydrophobic and promote improved NC film transfer, the substrate is functionalized with a chosen silane molecule. We surveyed four silane molecules including: [1] (3-mercaptopropyl)trimethoxysilane (MPTS), [2] (3,3,3-trifluoropropyl)trichlorosilane (FPTS), [3] methyltrimethoxysilane (MTS), and [4] triethoxyoctylsilane (TOS). All four silane molecules tested were effective for film transfer. The silane chemicals are stored in a N₂-filled glove box. Inside the glove box, 40 mL of anhydrous hexane is added to a glass jar, followed by dropwise addition of 100 μL of the silane to make a 0.25 vol % solution of the silane in anhydrous hexane. The solution is vigorously mixed for 10 min. In a fume hood, a bell jar is placed over a stir plate with a glass dish inside. The substrates are added to the glass dish followed by addition of the silane solution. Typically, several substrates are functionalized at the same time. A stir bar is used to stir the solution at a moderate rate, and the dish is covered. A humidity sensor is place on top of the covered dish, and the bell jar is covered. Advantageous results are obtained when the relative humidity level is between 15-30%. A line for dry air is connected to the bell jar inlet, the flow is tuned to adjust the relative humidity level in the bell jar accordingly, and the solution is stirred over the samples for 3 min. FIG. 8 shows some photographs of this setup for a single sample. After the 3-minute period, the substrates are removed and rinsed with chloroform, and then placed into a fresh chloroform solution and sonicated in a bath sonicator at medium level for at least 5 min to remove excess silane molecules not bound to the substrate surface. The substrate is rinsed once more with fresh chloroform and blown dry using a N₂ gun. The substrates are now ready for NC monolayer deposition by transferring the film from the liquid-air interface to the substrate using the Langmuir-Schaefer method as previously described.

Nanofabrication Processing

Summary of Dominant Dry Etch Mechanisms

The species which generally dominate the etching process in RIE are the neutral radicals. Directional ion bombardment assists the etch process to realize the formation of high-fidelity pattern transfer via an anisotropic etch profile. The RIE process can be broadly divided into two sub-categories: (1) inhibitor ion-enhanced and (2) energetic ion-enhanced. For an inhibitor-driven process, etching by neutral radicals is spontaneous and does not require ion bombardment. In these etch chemistries, a thin passivating polymer film forms on the substrate surfaces, inhibiting the spontaneous chemical etch process. Because ion bombardment is highly directional and normal to the substrate surface, the ion flux serves to degrade the formation of the passivating layer on the horizontal surfaces. In contrast, the sidewalls maintain the passivation layer which inhibits lateral etching from radicals. The result is an anisotropic etch profile with relatively vertical sidewalls. An example of this mechanism for etching silicon is CF₄-based etching. In the case of an energy-driven etch process, the neutral radical species by themselves cause little to no etching at all and require ion bombardment for the etching to occur. The ion bombardment provides sufficient energy to effectively “damage” the substrate surface in various ways, such as breaking certain bonds to form volatile byproducts. The dominant mechanisms in this category are highly dependent on the specific etch chemistry. The development of an anisotropic etch profile is a natural consequence of the high vertical directionality of the ion bombardment. An example of this mechanism for etching silicon is Cl₂-based etching.

Inductively Coupled Plasma Reactive Ion Etching (ICP RIE) Recipes

Dry Etch for Pattern Transfer: Substrates are etched using an Oxford Instruments PlasmaPro 100 Cobra ICP RIE. For the organic descum step an oxygen plasma is used. For pattern transfer into the underlying substrate material(s), two different etch chemistries are used including a CF₄/O₂ etch, and a Cl₂/Ar etch. A 2 mm thick 4-inch silicon carrier wafer is used to place samples into the etch chamber. TEM membranes are carefully secured on this carrier wafer using Kapton tape. The bulk silicon coupons are affixed to the carrier wafer using Crystalbond which promotes even thermal conductivity. A flake of the Crystalbond is placed between the wafer and backside of the sample substrate, then the carrier wafer is heated to 80° C. to melt the Crystalbond which fills the entire space between the sample and carrier wafer and makes the sample flat. The wafer is allowed to quickly cool to room temperature which solidifies the Crystalbond, securing the sample in place on the carrier wafer. After the etch is completed, the carrier wafer is heated to remelt the Crystalbond, and the samples are carefully removed from the wafer. The wafer surface and backside of the samples are carefully cleaned with a swab and acetone to remove residual organic residue from the Crystalbond.

O₂ Descum: An O₂ plasma is used to remove any residual, unwanted organics. The gas flow is set to O₂/Ar @ 45/5 sccm. A low-pressure strike (LPS) step is used for initiating and stabilizing the plasma. The target pressure is set to 5 mTorr, but the LPS is set to 8 mTorr with a 15 V minimum DC bias, and a ramp rate of 10. The etch proceeds at 5 mTorr, 1000 W (ICP), and 25 W (HF) (V_{dc} ˜23 V) at 10° C. for 20 s with a 10 Torr He backflow to maintain temperature uniformity and stability across the substrate.

CF₄/O₂ Etch Chemistry

Chamber Conditioning: A chamber conditioning step is used to prepare the chamber interior for CF₄-based etching. A designated 4-inch silicon wafer is placed in the load lock for the chamber condition process, which uses CF₄ @ 30 sccm, 15 mTorr, 1200 W (ICP), and 30 W (HF) for 15 min at 10° C. After the chamber is properly conditioned, the dummy wafer is removed and the carrier wafer with samples is placed into the tool.

Etch: The etching is conducted using a stabilization step, a strike step, and an etch step. The first step is used to stabilize the gas flow and chamber pressure at CF₄/O₂ @ 45/5 sccm and 8 mTorr. The strike step is used to strike a plasma at 8 mTorr and stabilize it for the actual etch step at 5 mTorr. The strike step uses a LPS setting of 8 mTorr, a minimum DC bias set to 20 V, with a ramp rate of 10. The settings for the strike step are: 5 mTorr, 750 W (ICP), 15 W (HF) (V_{dc}˜102 V) for 2 s. While the time is set to 2 s, during the LPS after ignition there is an additional 5 s of a lit plasma in real time while the system stabilizes before it starts to count down the 2 s time (totaling 7 s real time). The system then immediately transitions to the etch step which is set to: 5 mTorr, 650 W (ICP), 5 W (HF) (V_{dc} ˜49 V), and a time of 13 s for the TEM membranes or 3 s for the SiO₂ open step on bulk substrates. Thus, the sample is exposed to a lit plasma for a total of 20 s or 10 s in real time for the TEM membranes or bulk substrates, respectively. In all cases, the etching is conducted at 10° C. using a 10 Torr He backflow to maintain temperature uniformity and stability across the substrate. The added O₂ is meant to balance the formation of the fluorocarbon passivation layer on the sidewalls to ensure the nanoscale channel between the discrete NC masks is not completely passivated, and etching can proceed.

Chamber Clean: After the etch process is complete, a post-etch chamber cleaning procedure is used. A 4-inch sapphire substrate is placed in the load lock. The chamber clean is broken into five steps. The first step uses O₂ @ 40 sccm, 10 mTorr, 1000 W (ICP), and 150 W (HF) for 20 s. Step two uses O₂/SF₆ @ 40/15 sccm, 10 mTorr, 1500 W (ICP), and 50 W (HF) for 5 min. Step three uses O₂/SF₆ @ 40/15 sccm, 20 mTorr, 1800 W (ICP), and 20 W (HF) for 5 min. Step four uses O₂ @ 40 sccm, 10 mTorr, 1500 W(ICP), and 50 W (HF) for 5 min. The final step uses O₂ @ 40 sccm, 20 mTorr, 1800 W(ICP), and 20 W (HF) for 5 min.

Cl₂/Ar Etch Chemistry

Chamber Conditioning: A chamber conditioning step is used to prepare the chamber interior for Cl₂-based etching. A designated 4-inch silicon wafer is placed in the load lock for the chamber conditioning process which has two steps. The first step uses BCl₃/Cl₂/Ar @ 5/20/10 sccm at 10 mTorr, 1000 W (ICP), and 50 W (HF) for 1 minute. The second step uses BCl₃/Cl₂/Ar @ 5/20/5 sccm at 10 mTorr, 1000 W (ICP), and 10 W (HF) for 20 min. After the chamber is properly conditioned, the dummy wafer is removed and the carrier wafer with samples is placed into the tool.

Etch: The etching is conducted in an immediately sequential two-step process. The first step is designated as an SiO₂ etch to make sure we fully etch through any native oxide layer. This step uses BCl₃/Cl₂/Ar @ 5/20/10 sccm at 10 mTorr, 1000 W (ICP), and 50 W (HF) (V_{dc} ˜140 V) for 7 s. This is immediately followed by the silicon etch which is conducted using Cl₂/Ar @ 45/5 sccm at 10 mTorr, 1100 W (ICP), and 20 W (HF) (V_{dc} ˜90 V) for 15 s. In all cases, the etching is conducted at 10° C. using a He backflow to maintain temperature uniformity and stability across the substrate.

Chamber Clean: After the etch process is completed, at post-etch chamber cleaning procedure is used. A 4-inch sapphire substrate is placed in the load lock. The chamber clean is broken into 3 steps. The first step uses O₂ @ 40 sccm at 10 mTorr, 1000 W (ICP), and 150 W (HF) for 20 s. The second step uses O₂/SF₆ @ 40/40 sccm at 10 mTorr, 1500 W (ICP), and 50 W (HF) for 30 min. The third step uses O₂ @ 40 sccm at 10 mTorr, 1500 W (ICP), and 50 W (HF) for 30 min.

NC Removal

Chemically Selective Wet Etch: The SiO₂ layer is selectively removed without affecting the silicon substrate by placing the sample in a ˜10% HF solution for 3 min. 49% HF was diluted using a ratio of 4:1 DI H₂O:49% HF. The substrate is rinsed in fresh DI water three times, then blown dry with a N₂ gun. This process removes the thin layer of SiO₂, thus lifting off the GdF₃ NCs and leaving behind a clean, patterned silicon substrate.

Example of Process Adjustment for Cl₂-Based ICP RIE

We employ a design of experiments (DOE) approach to formulate and adjust a dry etch recipe. We will walk through the DOE approach used to adjust Cl₂-based etching using ICP RIE. We specifically focus on the Cl₂-based dry etch because this recipe is what is used for the main pattern transfer process into the bulk Si substrate. A complete DOE process was not employed for the CF₄ recipe, but choices for the CF₄-based dry etch were largely informed by observations made for the Cl₂-based DOE results. However, the CF₄ chemistry typically yields a higher V_{dc} than Cl₂ due to a higher ion population. If the DC bias becomes too high it can lead to undesirable physical sputtering and redeposition. Consequently, we used lower power settings for the CF₄ recipe relative to the Cl₂-based chemistry to ensure the V_{dc} was not too high to maintain a high-fidelity pattern transfer result.

Cl₂-based etching is an energy-driven dry etch chemistry that is commonly used to etch materials such as Si, Al, GaAs, and many other materials. Simple chemical adsorption is typically not enough to etch the substrate material, as the chloride byproduct requires additional energy from the physical bombardment of ions to proceed with desorption and etching. Therefore, it is common in Cl₂-based dry etching to add Ar in the mixture to increase the ion population. To investigate the settings for Cl₂ etching, we use a DOE approach based on a Taguchi method and identify key input variables for the etching procedure: ICP power, HF power, Ar content, and pressure. We then choose the number of levels we would like to test, where the interval is the same between each level for a respective input variable. We choose the starting values and corresponding intervals to be relatively broad to map out the experimental space more fully. We choose four input variables to test with three levels in each (Table 1). This experimental design leads to a factorial experimental matrix of 3⁴=81 independent experiments. We use a Taguchi L9 DOE to reduce the full experimental matrix to 9 experiments (Table 2) that will yield insightful data about the experimental space.

TABLE 1
The generalized input form for an experiment which consists
of four parameters (A-D) and three levels (1-3):

| Level | A | B | C | D |
|---|---|---|---|---|
| 1 | A1 | B1 | C1 | D1 |
| 2 | A2 | B2 | C2 | D2 |
| 3 | A3 | B3 | C3 | D3 |

TABLE 2
The generalized formulation of the reduced experimental
matrix for a Taguchi L9 DOE array which consists
of four parameters (A-D) and three levels (1-3):

| Run | A | B | C | D |
|---|---|---|---|---|
| 1 | A1 | B1 | C1 | D1 |
| 2 | A1 | B2 | C2 | D2 |
| 3 | A1 | B3 | C3 | D3 |
| 4 | A2 | B1 | C2 | D3 |
| 5 | A2 | B2 | C3 | D1 |
| 6 | A2 | B3 | C1 | D2 |
| 7 | A3 | B1 | C3 | D2 |
| 8 | A3 | B2 | C1 | D3 |
| 9 | A3 | B3 | C2 | D1 |

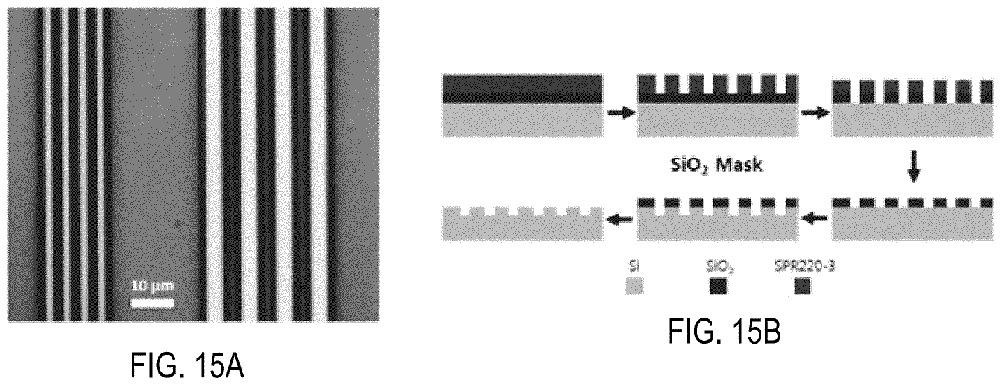

The first round of experiments should have wider interval choices for each parameter to test a broader range of the experimental space. Table 3 summarizes the chosen input variables for the first round of experiments which is referred to as DOE-1. Table 4 summarizes the corresponding experimental conditions for DOE-1 for experiments 1.1-1.9 based on the Taguchi L9 approach. The major goals of the first experimental round (DOE-1) are to better understand the general trends in the measured outcomes, and to narrow down the intervals and quantitative values for subsequent experiments. The sample morphology used for DOE-1 is described in FIG. 15. Photolithography was used to create line-space patterns down to 2 μm. The patterned resist was used to transfer the same line-space pattern into a layer of SiO2, then the resist layer was stripped. The patterned SiO₂ layer acts as a high selectivity etch mask to investigate the Cl2-based etch chemistry for etching Si. The Cl2 chemistry will not etch the SiO2 mask, and HF can be used to remove the SiO2 mask without affecting the underlying patterned Si substrate.

TABLE 3
Summary of the four experimental parameters for
Cl₂-based ICP RIE and the input choices for a Taguchi 3-level
DOE (L⁹). This represents the DOE-1 inputs.

| | ICP Power | HF Power | Ar Content | Pressure |
|---|---|---|---|---|
| Level | (W) | (W) | (%) | (mTorr) |
| 1 | 500 | 15 | 0 | 5 |
| 2 | 750 | 30 | 20 | 12 |
| 3 | 1000 | 45 | 40 | 19 |

TABLE 4
Summary of the reduced experimental matrix used
to conduct DOE-1 based on the Taguchi L⁹ method.

| | ICP Power | HF Power | Ar Content | Pressure |
|---|---|---|---|---|
| Run | (W) | (W) | (%) | (mTorr) |
| 1.1 | 500 | 15 | 0 | 5 |
| 1.2 | 500 | 30 | 20 | 12 |
| 1.3 | 500 | 45 | 40 | 19 |
| 1.4 | 750 | 15 | 20 | 19 |
| 1.5 | 750 | 30 | 40 | 5 |
| 1.6 | 750 | 45 | 0 | 12 |
| 1.7 | 1000 | 15 | 40 | 12 |
| 1.8 | 1000 | 30 | 0 | 19 |
| 1.9 | 1000 | 45 | 20 | 5 |

SiO₂ was deposited using plasma-enhanced chemical vapor deposition (PECVD) at 350° C., with silane (90% He) @ 85 sccm, N₂O @ 710 sccm, 1000 mTorr, and 20 W. This recipe yields a deposition rate of ˜58 nm/min. 96 nm was deposited over 100 s. Surpass 4k was spin-coated on the SiO₂ surface at 3500 rpm for 45 s and rinsed with isopropyl alcohol in the last 15 s. SPR220-3 resist was then spin-coated at 5000 rpm for 60 s, then baked at 115° C. for 90 s. The resist was exposed using a laser direct-write system (Heidelberg DWL 66+) with a 2 mm write head, 190 mW, 50% intensity, a 1% filter, 60% focus, and dose equal to 1. After exposure, 10 min was allowed to pass, then the resist was developed in MF26A for 60 s and rinsed with DI water. The sample was then baked at 115° C. for 60 s. A descum was employed using a capacitively coupled plasma (CCP) RIE system (Oxford Plasmalab 80 Plus) with O₂ @ 20 sccm, 40 mTorr, 100 W, and 60 s. An optical image of the patterned resist is shown in FIG. 2.8A. The SiO₂ hard mask layer was then etched using the CCP system with CF₄ @ 20 sccm, 25 mTorr, 150 W, for 180 s. Nine samples were used for DOE-1 for Si etching according to Table 2.4 with a 20 s etch duration at 10° C. After the dry etch, the SiO₂ mask was removed by wet etching in 49% HF for 5 min before sample characterization.

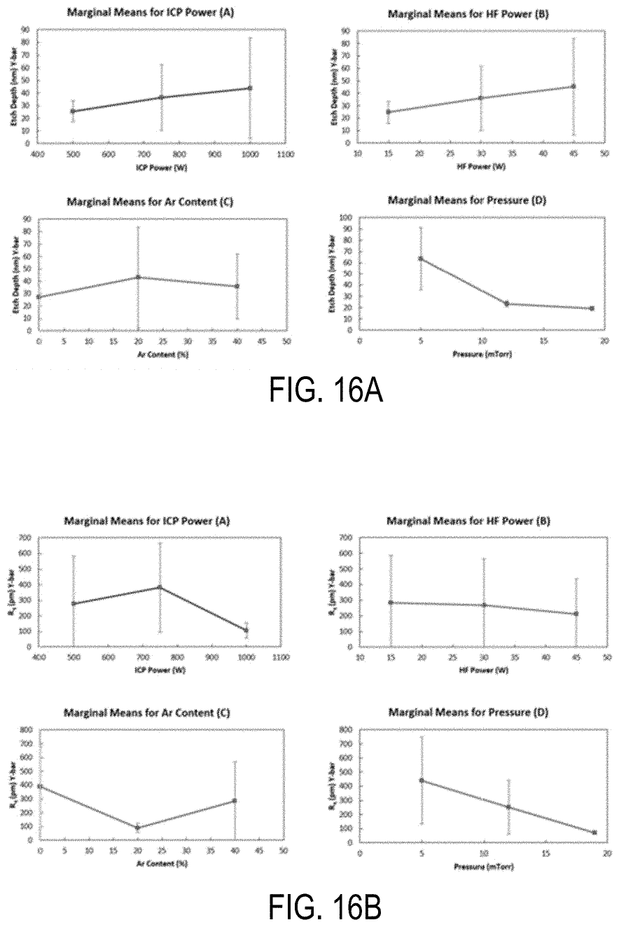

After the samples have been processed, as illustrated in FIG. 15, the next step is to characterize some measurable outputs of interest. We consider two outputs which we measure using AFM in tapping mode: 1) etch depth and 2) surface roughness (R_{q}) in the etched trench. For each run in DOE-1, we make four measurements at different locations on the sample for the respective output. Each of these four measurements results from a line cut taken perpendicular to the trench orientation and averaged over 100 pixels. The reported mean and standard deviation (σ) are across the four measurements (Y1-Y4) for each run. The output results presented in Table 5 are used to create marginal means plots for each input parameter, as shown in FIG. 16.

Since there are four input variables (A-D), there are four plots for each output measurement: etch depth and R_{q} in the present example. Given the experimental matrix implemented for DOE-1, each data point in each marginal means plot represents the mean of three output measurements. For example, if we take the data point for an HF power of 15 W on the etch depth plot in FIG. 16A, three samples had HF power set to 15 W (1.1, 1.4, and 1.7). That single data point is the mean of the etch depth for those three samples, and the error bar represents the standard deviation based on those three mean measurements. Many of the data points have large error bars. This is common for a first-round DOE because the chosen intervals are large, leading to significant differences in the measured outputs. A large standard deviation also indicates that more than one of the input variables likely has a considerable effect on the given output for the chosen quantitative intervals.

TABLE 5
Summary of the outputs 1) etch depth and 2) R_{q} measured
by AFM characterization, and the corresponding mean
and standard deviation for each run in DOE-1.
Etch Depth (nm)

| Run | Y1 | Y2 | Y3 | Y4 | Mean | σ |
|---|---|---|---|---|---|---|
| 1.1 | 34.7 | 35.2 | 34.7 | 34.4 | 34.75 | 0.33 |
| 1.2 | 22.4 | 22.0 | 21.8 | 22.0 | 22.05 | 0.25 |
| 1.3 | 19.8 | 19.4 | 19.5 | 19.7 | 19.60 | 0.18 |
| 1.4 | 17.3 | 17.4 | 17.5 | 17.6 | 17.45 | 0.13 |
| 1.5 | 64.9 | 65.4 | 65.8 | 67.2 | 65.83 | 0.99 |
| 1.6 | 26.2 | 26.4 | 26.6 | 25.9 | 26.28 | 0.30 |
| 1.7 | 21.9 | 21.7 | 21.6 | 21.9 | 21.78 | 0.15 |
| 1.8 | 20.2 | 20.0 | 20.3 | 20.2 | 20.18 | 0.13 |
| 1.9 | 89.6 | 89.7 | 89.8 | 90.0 | 89.78 | 0.17 |

R_{q} (pm)

| Y1 | Y2 | Y3 | Y4 | Mean | σ |
|---|---|---|---|---|---|
| 550.9 | 562.2 | 722.9 | 679.5 | 628.88 | 85.50 |
| 103.7 | 132.0 | 136.8 | 120.1 | 123.15 | 14.75 |
| 90.3 | 81.1 | 77.2 | 77.4 | 81.50 | 6.13 |
| 67.2 | 55.1 | 56.9 | 61.5 | 60.18 | 5.40 |
| 687.7 | 721.3 | 615.8 | 414.3 | 609.78 | 137.55 |
| 417.0 | 530.3 | 504.7 | 430.0 | 470.50 | 55.52 |
| 140.4 | 176.5 | 173.8 | 154.8 | 161.38 | 16.99 |
| 68.2 | 68.4 | 70.5 | 77.7 | 71.20 | 4.46 |
| 96.8 | 89.4 | 73.9 | 78.8 | 84.73 | 10.33 |

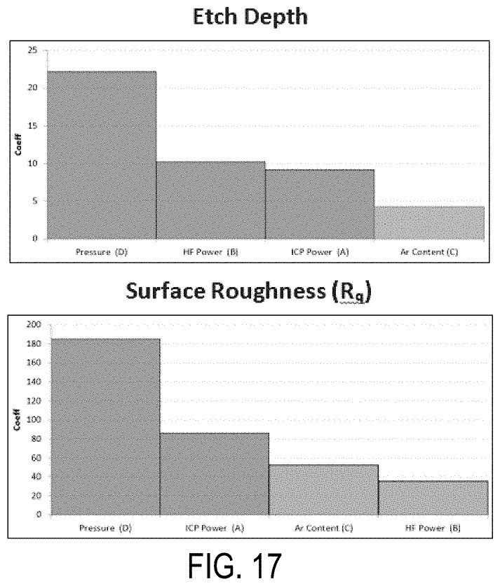

Pareto analysis was performed on the output measurements to understand more about each input parameter's relative significance on the respective output measurement as shown in FIG. 17. For etch depth, which is effectively a measure of etch rate, we see that pressure is the most influential parameter. HF power and ICP power are moderately influential and similar, and the Ar content is the least significant. For surface roughness, pressure is also the most significant parameter. However, ICP power is the second most influential, followed by Ar content, and finally HF power, which has the least significant influence for R_{q}. Given these results, we must now re-evaluate the input parameters for the next round of experiments for DOE-2.

The results presented in FIG. 17 reveal pressure is a key factor for both etch rate and surface roughness. Pressure dictates the mean free path of molecules in the etch chamber. Therefore, pressure has a significant influence on molecular motion and the etch profile. Based on the results from DOE-1, a higher pressure tends to lead to a lower roughness. While the etch rate is lower with higher pressure, it has a low standard deviation on the marginal means plot, and we are not necessarily concerned with a high etch rate since we are aiming for a relatively small etch depth. Higher ICP power leads to a higher etch rate due to increased ion population.

While there are considerable error bars in etch depth for higher ICP power, we are more concerned with the fact that a higher ICP power yields a low R_{q} with a small error. HF power is not as key for either output. Increased HF power leads to a slightly increased etch rate and a slightly decreased surface roughness. However, HF power does dictate the overall ion energy distribution, which is a consideration when considering NC mask erosion. The highest power case for experiment 1.9 could lead to undesirable sputtering, especially for NC masks, meaning we need to be at least below that threshold. The Ar content is less key for the etch rate but is moderately significant for surface roughness. 20% Ar yielded the smallest mean R_{q} with the smallest error, meaning the Ar ion-assisted process is necessary for uniformity. With all these effects in mind, we determine the experimental procedure for DOE-2 as summarized by Table 6 and Table 7.

TABLE 6
Summary of four experimental parameters for Cl₂-based
ICP RIE and the input choices for a Taguchi 3-level DOE
(L⁹). This represents the DOE-2 inputs.

| | ICP Power | HF Power | Ar Content | Pressure |
|---|---|---|---|---|
| Level | (W) | (W) | (%) | (mTorr) |
| 1 | 1000 | 20 | 0 | 10 |
| 2 | 1100 | 25 | 10 | 15 |
| 3 | 1200 | 30 | 20 | 20 |

TABLE 7
Summary of the reduced experimental matrix used
to conduct DOE-2 based on the Taguchi L⁹ method.

| | ICP Power | HF Power | Ar Content | Pressure |
|---|---|---|---|---|
| Run | (W) | (W) | (%) | (mTorr) |
| 2.1 | 1000 | 20 | 0 | 10 |
| 2.2 | 1000 | 25 | 10 | 15 |
| 2.3 | 1000 | 30 | 20 | 20 |
| 2.4 | 1100 | 20 | 10 | 20 |
| 2.5 | 1100 | 25 | 20 | 10 |
| 2.6 | 1100 | 30 | 0 | 15 |
| 2.7 | 1200 | 20 | 20 | 15 |
| 2.8 | 1200 | 25 | 0 | 20 |
| 2.9 | 1200 | 30 | 10 | 10 |

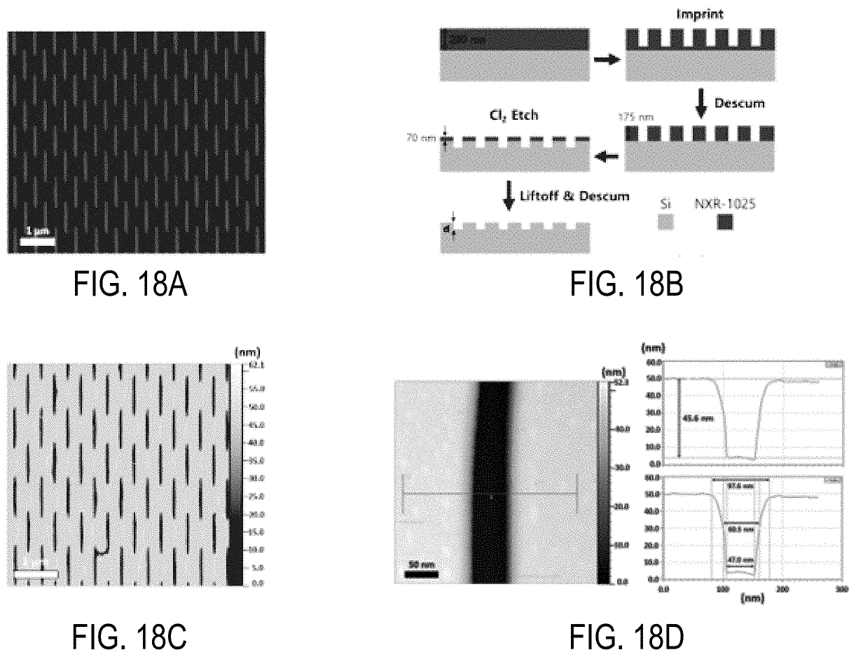

In DOE-1, we fabricated and characterized microscale features. This works well for early-stage investigation of a new etch chemistry. As feature size is scaled down to the nanoscale, however, some aspects such as etch rate or etch profile can be different from what is observed for larger features due to increased confinement, which can affect molecular transport. In DOE-2, we fabricate nanoscale features using nanoimprint lithography (NIL). FIG. 18A shows a top-down SEM image of the silicon master stamp used for the imprint, which consists of an array of discrete lines with a length of 1 μm and a width of 100 nm. The lines have a height of ˜185 nm.

FIG. 18B shows a cross-sectional schematic of the NIL process and subsequent pattern transfer using Cl₂-based ICP RIE. Nanonex thermal resist (NXR-1025) at 7 wt % in anisole is spin-coated on a clean Si substrate at 2250 rpm for 60 s, then baked at 155° C. for 3 min, leading to a thickness of ˜206 nm. A Nanonex imprint tool is used to imprint the hard Si stamp in the resist. The chamber is evacuated for 3 min; the pre-imprint is set to 133° C. and 120 PSI, then the imprint is performed at 133° C. and 350 PSI for 5 min and 30 s. The cooling and vent step is performed at 55° C. A CCP RIE system is used to perform a descum using O₂ @ 100 sccm, 150 W, 40 mTorr, for 10 s. Nine samples are then used for DOE-2 to understand further and adjust the Cl₂-based etch recipe.

FIG. 18C shows an AFM height image of the Si surface after pattern transfer, liftoff, and descum for sample 2.1, with discretely patterned trenches. A higher magnification of a single trench from sample 2.1 is shown in FIG. 18D. The corresponding trench profile is plotted to the right to show relevant profile measurements. These data offer the ability to calculate the sidewall slope of the trench. This characterization and analysis were performed on all samples for DOE-2.

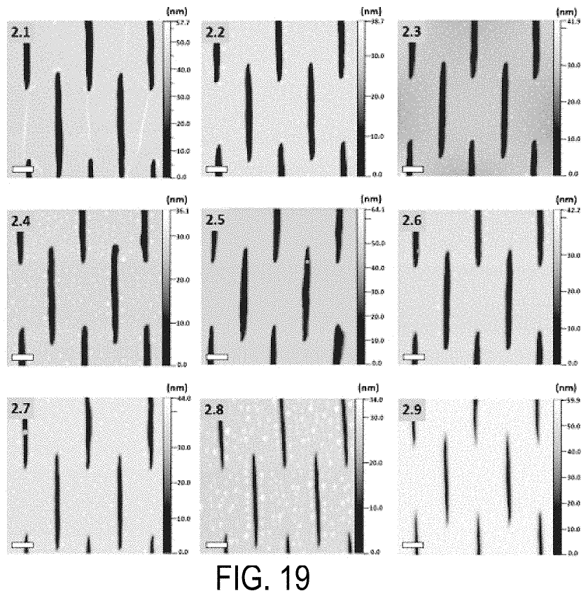

FIG. 19 provides a representative AFM height image for samples 2.1-2.9. Each sample was analyzed using AFM to investigate three output measurements: 1) etch depth, 2) surface roughness in the trench (R_{q}), and 3) sidewall slope. Furthermore, we want the resulting V_{dc} (monitored by the etch tool) to be moderate since undesirable sputtering can occur if the bias is too high. The data analysis process for DOE-2 is essentially the same as was presented for DOE-1.

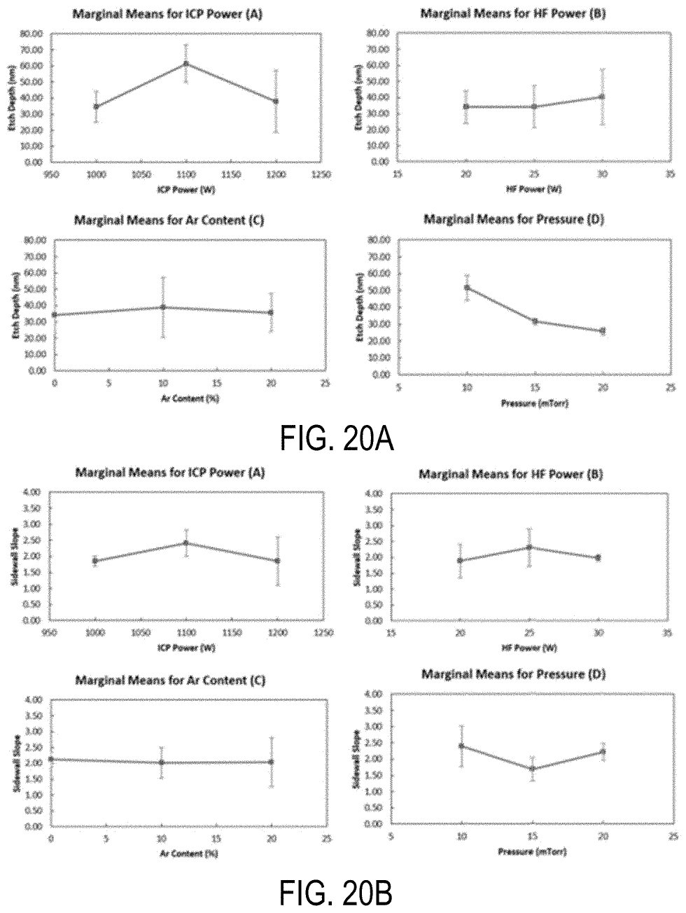

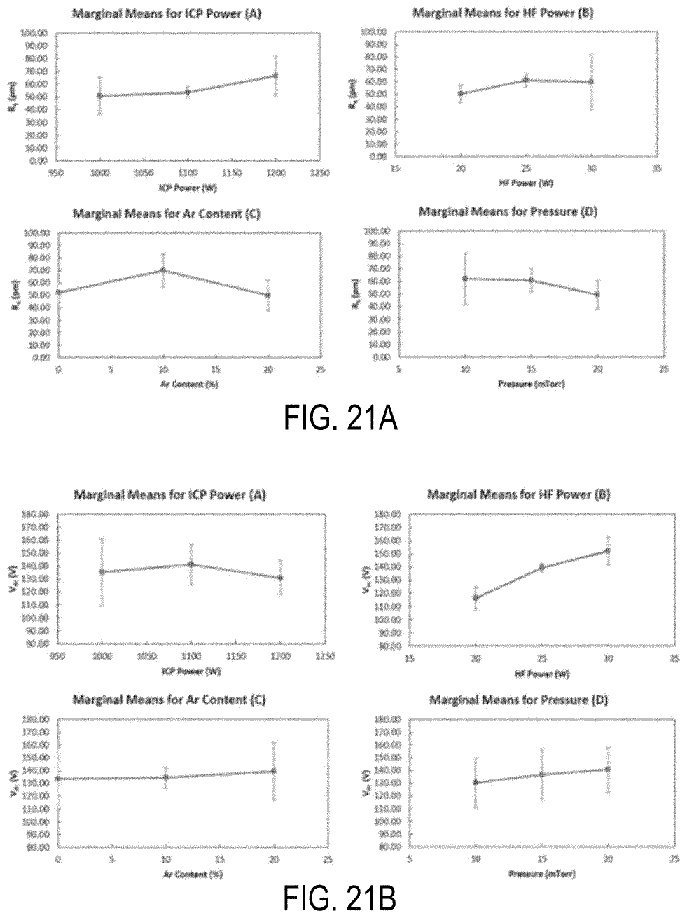

FIG. 20 summarizes the marginal means plots for etch depth and sidewall slope, and FIG. 21 summarizes the marginal means plots for roughness and V_{dc}. For the sake of conciseness, we will not explicitly walk through each part of the data for DOE-2 but will highlight the goals of the analysis. To maintain high-fidelity pattern transfer, we are most interested in a vertical sidewall, low roughness, a reasonable etch rate, and a moderate V_{dc}. The data analysis led to the following etch conditions for Cl₂-based ICP RIE, which are generally considered an suitable starting point given the listed goals:

Si Etch: Cl₂/Ar A 45/5 sccm, 1100 W (ICP), 20 W (HF), 10 mTorr, 10° C.

One might note two points: 1) Cl₂ alone will not etch SiO₂, so we first introduce a brief native oxide etch immediately followed by the nominal Si etch. 2) This recipe is meant to serve as a starting point for pattern transfer of nanoscale features into Si using Cl₂ ICP RIE.

Experimental Characterization

Transmission Electron Microscopy: TEM characterization was conducted using a JEOL 1400 TEM operated at 120 kV in bright-field mode.

Scanning Electron Microscopy: SEM characterization was conducted using a JEOL 7500F SEM. Images were acquired using the high-resolution setting, a beam energy of 2 kV, a 20 μA beam current, a probe current setting of 6, and a WD=3 mm using the SEI detector. Cross-sectional SEM was performed on bulk Si substrates by cleaving the samples. This type of characterization is not practical for the TEM samples, as the patterned membranes (SiNₓ and SiO₂) are destroyed when attempting to cleave the samples.

Atomic Force Microscopy: AFM characterization was conducted using an Asylum Research MFP-3D-Bio AFM. For high spatial resolution with minimal tip convolution, a specialized probe was used for characterization. The probe used was the HiRes-Cl4/Cr—Au probe from MikroMasch that has a super sharp carbon spike on the end of a silicon probe. This probe is used in tapping mode and manually tuned using a drive frequency of ˜127 kHz, a sweep width of ˜2.35 kHz, drive amplitude of 11.60 mV, a Q gain of 0.0, a phase offset of ˜176°, and an input range of ±10 V. The free air amplitude should be ˜524 mV, the frequency ˜127 kHz, and a resulting Q of ˜286. The scan was conducted using 512 points and lines, a scan angle of 90°, and scan rate of 0.60 Hz. The probe is very slowly and gently engaged with the sample surface. The set point is set to 450 mV, then the probe is engaged, and the head should be lowered until the Z voltage is ˜40. The set point is slowly decreased, and the Z voltage consequently increases until saturation when the set point reaches ˜330-360 mV. The probe should then be operating in “attractive” mode with a phase between 110°-130°. The final imaging conditions were a set point of 324.77 mV, drive amplitude of 11.60 mV, drive frequency of 126.939 kHz, and an integral gain of 4.00. The exact values of frequency and phase will vary a little and are dependent on the specific probe used, as there is inherently variation between different probes even if it is the same kind.

Small Angle X-ray Scattering: The SAXS patterns were measured using a 1 mm glass capillary (Charles Supper) filled with the NC dispersion in toluene at a concentration of ˜10 mg/mL and sealed using a hot-glue gun. The data were collected using a Pilatus 1M detector on a Xeuss 2.0 system from Xenocs by combining the results from two different sample-to-detector distances—363 mm and 1210 mm. The two-dimensional scattering patterns were first azimuthally averaged, then the one-dimensional curves were combined. Finally, the background signal contribution from the capillary tube filled with toluene was subtracted. The integration time was set to 30 min. The q-range was calibrated against a silver behenate standard. A copper anode source was used with a beam energy of 8 keV.

Ellipsometry: The film thickness of the thermally grown SiO₂ layer was measured using a J. A. Woollam V VASE spectroscopic ellipsometer to be ˜7.3±0.2 nm. Measurements were made several times across different areas of a 4-inch wafer and indicated very high uniformity.

Photoluminescence Measurements: Light from a 980 nm laser (CNI MDL-III-980) is spatially filtered and focused to the sample through a 50×, NA 0.8 objective (Olympus MPlanFL N). Photoluminescence (PL) is collected through the same objective and focused to an optical fiber which is coupled to a spectrometer (Horiba iHR550 monochromator and Symphony II CCD), The excitation beam is filtered from the signal via two 950 nm short-pass filters (Newport 10SWF-950-B) placed before the fiber.

X-Ray Simulation

SAXS Simulation: The x-ray simulation was performed in the manner used by Gordon et al.⁵ This method uses an atomistic model of the nanocrystalline rhombic plate geometry—for which the dimensions and crystal lattice were determined using information from TEM and XRD characterization˜to accurately simulate the expected SAXS pattern with the distinct particle morphology and size statistics. The x-ray simulation uses the Debye equation to calculate the x-ray scattering intensity I(q) as a function of the scattering parameter q, the distance between atoms rₘₙ, and the atomic form factors Fₘ and Fₙ. The Debye formula allows calculation of the x-ray scattering intensity at any angle θ for a given set of atomistic coordinates. The form factors are calculated using Cromer-Mann coefficients (which are dependent on the atomic species), and are multiplied by a temperature factor which considers the Debye-Waller factor B. The Debye equation is discretized by binning identical distances in the structure to improve calculation time. For this experiment, the GdF₃ orthorhombic unit cell for the atomistic model was made using lattice parameters a=6.518 Å, b=6.950 Å, and c=4.389 Å and α=β=γ=90°. The nanocrystals were simulated as a rhombic plate where the b-axis is the short dimension with thickness t=2.2 nm. The rhombus shape was cut from a square plate along the {101} directions. The mean size A=37.7 nm was used for the length with a standard deviation σ=1.7 nm. Size distribution is accounted for using a Gaussian weighted sum of 21 discrete x-ray patterns from individual nanocrystals using two standard deviations. The x-ray simulation used a 2θ step size of 0.001° with a range from 0°-15°, and an input of 2.0 was used for the Debye-Waller Factor (DWF). The simulation output provides intensity at each value of 2θ. The 2θ value was converted to q to plot the SAXS data using the equation q=4π sin sin(θ)/λ, where θ is input in radians, and the wavelength λ=0.1540562 nm for a Cu radiation source. To account for poor counting statistics at high q for the experimental data, a baseline intensity of 1.0×10⁻⁴ was added to the simulated intensity over the entire q-range for direct comparison to the experimental data.

### ASPECTS

The following Aspects are illustrative only and do not limit the scope of the present disclosure or the appended claims. Any part of any Aspect can be combined with any part or parts of any other Aspect or Aspects.

Aspect 1. A patterning method, comprising: disposing a nanoparticle composition (that comprises nanoparticles) on a support material, the nanoparticle composition optionally comprising nanocrystals, the disposing being performed such that the nanoparticle composition defines a patterned region having an average inter-nanoparticle distance of less than about 5 nm; and selectively etching the support material so as to give rise to in the support material a plurality of arrayed structures substantially in register with the patterned region of the nanoparticle composition.

It should be understood that the nanoparticles of the nanoparticle composition can be present as nanocrystals (i.e., a nanoparticle can be a nanocrystal), although this is not a requirement.

As shown in FIGS. 1A-1C, one can etch a surface treatment on the support material (e.g., SiO₂) and also etch the support material itself

As shown in FIGS. 1A1C the support material can be SiO₂; other materials can also be used. The support material can be an etchable material; as shown in FIGS. 1A1C, one can etch a surface coating (e.g., a silane) atop a support material and also etch the support material itself

Aspect 2. The method of Aspect 1, wherein the nanoparticle composition comprises nanoparticles that include one or more rare earth elements.

Aspect 3. The method of Aspect 1, wherein the nanoparticles comprise rare earth fluoride compounds.

Aspect 4. The method of any one of Aspects 1-3, wherein the nanoparticles comprise ligands present thereon. Ligands can be removable, e.g., via the described O₂ descum process.

Aspect 5. The method of Aspect 4, wherein the ligands are dendritic.

Aspect 6. The method of any one of Aspects 1-5, wherein the nanoparticles are characterized as non-spherical.

Aspect 7. The method of Aspect 6, wherein the nanoparticles are characterized as rhombic.

Aspect 8. The method of any one of Aspects 1-7, wherein the nanoparticles comprise GdF₃.

Aspect 9. The patterning method of any one of Aspects 1-8, wherein the nanoparticle composition self-assembles so as to form the patterned region.

Aspect 10. The method of Aspect 1, wherein the support material is disposed on a substrate, and further comprising etching the substrate (which etching can be selective) so as to give rise to in the substrate a plurality of arrayed structures substantially in register with the patterned region of the nanoparticle composition.

The substrate can be, e.g., silicon (Si), SiO₂, SiNₓ, a semiconductor (e.g., GaAs), a magnetic material, a dielectric material, an amorphous material, a quantum materials (e.g., doped diamond or 2D materials), or any combination thereof. (The foregoing list of substrate materials is illustrative and non-limiting). As described elsewhere herein, the substrate can be etchable.

As shown in FIG. 2, one can control the humidity in the region above the nanocrystal (nanoparticle) dispersion so as to reduce the evaporation rate of a solvent in which the nanocrystals (nanoparticles) are dispersed and allow self-assembly to occur.

Aspect 11. An article, comprising an article made according to any one of Aspects 1-10.

Aspect 12. A workpiece, comprising: an etchable support material; and a nanoparticle composition, the nanoparticle composition optionally comprising nanocrystals, the nanoparticle composition being disposed on the etchable support material as a monolayer, the nanoparticle composition defining a patterned region having an average inter-nanoparticle distance of less than about 5 nm, and nanoparticles (which can, again, be present as nanocrystals) of the nanoparticle composition optionally having ligands disposed thereon.

A ligand can be, e.g., a dendrimer ligand, such as G2. A ligand can also be, e.g., an oleate ligand. It should be understood that the claimed technology can include ligand exchange, e.g., exchanging a first ligand present on the nanoparticle composition with a second ligand. A ligand can be removed, e.g., via an O₂ descum process.

Aspect 13. The workpiece of Aspect 12, wherein the etchable support material defines therein a plurality of arrayed structures substantially in register with the patterned region of the nanoparticle composition. The support material can be, e.g., a silane or other hydrophobic treatment.

Aspect 14. The workpiece of any one of Aspects 12-13, further comprising an etchable substrate, the etchable support material being disposed on the etchable substrate.

Aspect 15. The workpiece of Aspect 14, wherein the etchable substrate defines therein a plurality of arrayed structures substantially in register with the patterned region of the nanoparticle composition.

Aspect 16. An article, comprising: a substrate, the substrate having formed therein a plurality of structures arranged arrayed periodically, the structures defining an average inter-structure spacing of less than about 5 nm.

Aspect 17. The article of Aspect 16, wherein the substrate comprises silicon (Si), SiO₂, SiNₓ, a semiconductor (e.g., GaAs), a magnetic material, a dielectric material, an amorphous material, a quantum materials (e.g., doped diamond or 2D materials), or any combination thereof.

Si, SiO₂, and SiNₓ are particularly suitable support materials, but the presently disclosed technology is not limited to these materials.

Aspect 18. The article of any one of Aspects 16-17, wherein the structures are characterized as pillars or mesas.

Aspect 19. The article of any one of Aspects 16-18, wherein a structure defines a cross-sectional dimension in the range of from about 1 to about 100 nm. The cross-sectional dimension (e.g., a width) can be, e.g., from about 1 to about 100 nm, or from about 2 to about 90 nm, or from about 3 to about 80 nm, or from about 4 to about 70 nm, or from about 5 to about 60 nm, or from about 6 to about 50 nm, or from about 7 to about 40 nm, or from about 8 to about 30 nm, or from about 9 to about 20 nm. A structure an define a height (which can be the structure's height extending away and past the substrate, e.g., distance din FIG. 5 and in FIG. 10) in the range of from about 1 to about 100 nm, or from about 2 to about 90 nm, or from about 3 to about 80 nm, or from about 4 to about 70 nm, or from about 5 to about 60 nm, or from about 6 to about 50 nm, or from about 7 to about 40 nm, or from about 8 to about 30 nm, or from about 9 to about 20 nm. A structure can define an aspect ratio (i.e., height:width) of from about 100:1 to about 1:100, or from about 97:1 to 1:97, or from about 90:1 to about 1:90, or from about 80:1 to about 1:80, or from about 70:1 to about 1:70, or from about 60:1 to about 1:60, or from about 50:1 to about 1:50, or from about 40:1 to about 1:40, or from about 30:1 to about 1:30, or from about 20:1 to about 1:20, or from about 10:1 to about 1:10, or from about 5:1 to about 1:5, or from about 3:1 to about 1:3, or from about 2:1 to about 1:2, or even about 1:1.

Aspect 20. The article of any one of Aspects 16-19, wherein the structures are polygonal in cross-section. A structure can be, e.g., rhombic in cross-section, square in cross-section, triangular in cross-section, rectangular in cross-section, or otherwise polygonal in cross section.

An article according to the present disclosure (e.g., an article according to any one of Aspects 16-20) can be incorporated into a receiver and/or into a transmitter. The article can be incorporated into a sensor, for example. The article can be configured as, for example, a circuit (including an integrated circuit, a memory device, an optoelectronics device, a plasmonic metasurface (e.g., for chemical or biological sensing applications), or a quantum device.

### REFERENCES

Santhanam, V.; Liu, J.; Agarwal, R.; Andres, R. P. Self-Assembly of Uniform Monolayer Arrays of Nanoparticles. Langmuir 2003, 19, 7881-7887. https://doi.org/10.1021/1a0341761.

Dong, A.; Chen, J.; Vora, P. M.; Kikkawa, J. M.; Murray, C. B. Binary Nanocrystal Superlattice Membranes Self-Assembled at the Liquid-Air Interface. Nature 2010, 466 (7305), 474-477. https://doi.org/10.1038/nature09188.

Ye, X.; Collins, J. E.; Kang, Y.; Chen, J.; Chen, D. T. N.; Yodh, A. G.; Murray, C. B. Morphologically Controlled Synthesis of Colloidal Upconversion Nanophosphors and Their Shape-Directed Self-Assembly. PNAS 2010, 107 (52), 22430-22435. https://doi.org/10.1073/pnas.1008958107/-/DCSupplemental.

Elbert, K. C.; Vo, T.; Krook, N. M.; Zygmunt, W.; Park, J.; Yager, K. G.; Composto, R. J.; Glotzer, S. C.; Murray, C. B. Dendrimer Ligand Directed Nanoplate Assembly. ACS Nano 2019, 13, 14241-14251. https://doi.org/10.1021/acsnano.9b07348.

Yoon, G.; Tanaka, T.; Zentgraf, T.; Rho, J. Recent Progress on Metasurfaces: Applications and Fabrication. J. Phys. D. Appl. Phys. 2021, 54, 383002. https://doi.org/10.1088/1361-6463/ac0faa.

Shi, H.; Zhu, X.; Zhang, S.; Wen, G.; Zheng, M.; Duan, H. Plasmonic Metal Nanostructures with Extremely Small Features: New Effects, Fabrication and Applications. Nanoscale Adv. 2021, 3, 4349-4369. https://doi.org/10.1039/d1na00237f.

Zheng, Z.; Zu, X.; Zhang, Y.; Zhou, W. Rational Design of Type-II Nano-Heterojunctions for Nanoscale Optoelectronics. Materials Today Physics. Elsevier Ltd Dec. 1, 2020. https://doi.org/10.1016/j.mtphys.2020.100262.

Marinica, D. C.; Kazansky, A. K.; Nordlander, P.; Aizpurua, J.; Borisov, A. G. Quantum Plasmonics: Nonlinear Effects in the Field Enhancement of a Plasmonic Nanoparticle Dimer. Nano Lett 2012, 12, 46. https://doi.org/10.1021/nl300269c.

Hatab, N. A.; Hsueh, C.-H.; Gaddis, A. L.; Retterer, S. T.; Li, J.-H.; Eres, G.; Zhang, Z.; Gu, B. Free-Standing Optical Gold Bowtie Nanoantenna with Variable Gap Size for Enhanced Raman Spectroscopy. Nano Lett. 2010, 10, 4952-4955. https://doi.org/10.1021/nl102963g.

Xiang, Q.; Zhu, X.; Chen, Y.; Duan, H. Surface Enhanced Raman Scattering of Gold Nanoparticles Supported on Copper Foil with Graphene as a Nanometer Gap. Nanotechnology 2016, 27. https://doi.org/10.1088/0957-4484/27/7/075201.

Dong, L.; Yang, X.; Zhang, C.; Cerjan, B.; Zhou, L.; Tseng, M. L.; Zhang, Y.; Alabastri, A.; Nordlander, P.; Halas, N. J. Nanogapped Au Antennas for Ultrasensitive Surface-Enhanced Infrared Absorption Spectroscopy. Nano Lett. 2017, 17 (9), 5768-5774. https://doi.org/10.1021/acs.nanolett.7b02736.

Regmi, R.; Berthelot, J.; Winkler, P. M.; Mivelle, M.; Proust, J.; Bedu, F.; Ozerov, I.; Begou, T.; Lumeau, J.; Rigneault, H.; Garcia-Parajó, M. F.; Bidault, S.; Wenger, J.; Bonod, N. All-Dielectric Silicon Nanogap Antennas to Enhance the Fluorescence of Single Molecules. Nano Lett. 2016, 16 (8), 5143-5151. https://doi.org/10.1021/acs.nanolett.6b02076.

Laible, F.; Horneber, A.; Fleischer, M. Mechanically Tunable Nanogap Antennas: Single-Structure Effects and Multi-Structure Applications. Adv. Opt. Mater. 2021, 2100326. https://doi.org/10.1002/ADOM.202100326.

Baghdadi, R.; Arpaia, R.; Charpentier, S.; Golubev, D.; Bauch, T.; Lombardi, F. Fabricating Nanogaps in YBa2Cu3 O7-δ for Hybrid Proximity-Based Josephson Junctions. Phys. Rev. Appl. 2015, 4. https://doi.org/10.1103/PhysRevApplied.4.014022.

Regan, B.; Trycz, A.; Froch, J. E.; Schaeper, O. C.; Kim, S.; Aharonovich, I. Nanofabrication of High Q, Transferable Diamond Resonators. Nanoscale 2021, 13, 8848-8854. https://doi.org/10.1039/d1nr00749a.

Kagan, C. R.; Bassett, L. C.; Murray, C. B.; Thompson, S. M. Colloidal Quantum Dots as Platforms for Quantum Information Science. Chemical Reviews. American Chemical Society Mar. 10, 2021, pp 3186-3233. https://doi.org/10.1021/acs.chemrev.0c00831.

Wu, B.; Kumar, A. Extreme Ultraviolet Lithography: A Review. J. V_{dc}. Sci. Technol. B Microelectron. Nanom. Struct. Process. Meas. Phenom. 2007, 25, 1743. https://doi.org/10.1116/1.2794048.

Suzuki, J.; Furukawa, T.; Miyata, H.; Shiratani, M.; Naruoka, T.; Maruyama, K.; Nakagawa, H.; Nagai, T. Novel EUV Photoresist for Sub-7 Nm Node. J. Photopolym. Sci. Technol. 2017, 30 (6), 671-674.

Wood, O. R. EUVL: Challenges to Manufacturing Insertion. J. Photopolym. Sci. Technol. 2017, 30 (5), 599-604.

Levinson, H. J.; Brunner, T. A. Current Challenges and Opportunities for EUV Lithography. In Proceedings of SPIE; SPIE-Intl Soc Optical Eng, 2018; p 2. https://doi.org/10.1117/12.2502791.

Baglin, J. E. E. Ion Beam Nanoscale Fabrication and Lithography—A Review. Appl. Surf. Sci. 2012, 258, 4103-4111. https://doi.org/10.1016/j.apsusc.2011.11.074.

Stanford, M. G.; Lewis, B. B.; Mahady, K.; Fowlkes, J. D.; Rack, P. D. Review Article: Advanced Nanoscale Patterning and Material Synthesis with Gas Field Helium and Neon Ion Beams. J. Vac. Sci. Technol. B, Nanotechnol. Microelectron. Mater. Process. Meas. Phenom. 2017, 35 (3), 030802. https://doi.org/10.1116/1.4981016.

Lewis, S. M.; Hunt, M. S.; Derose, G. A.; Alty, H. R.; Li, J.; Wertheim, A.; De Rose, L.; Timco, G. A.; Scherer, A.; Yeates, S. G.; Winpenny, R. E. P. Plasma-Etched Pattern Transfer of Sub-10 Nm Structures Using a Metal-Organic Resist and Helium Ion Beam Lithography. Nano Lett. 2019, 19, 6043-6048. https://doi.org/10.1021/acs.nanolett.9b01911.

He, S.; Tian, R.; Wu, W.; Li, W. Di; Wang, D. Helium-Ion-Beam Nanofabrication: Extreme Processes and Applications. Int. J. Extrem. Manuf. 2021, 3. https://doi.org/10.1088/2631-7990/abc673.

Hu, W. (Walter); Sarveswaran, K.; Lieberman, M.; Bernstein, G. H. Sub-10 Nm Electron Beam Lithography Using Cold Development of Poly(Methylmethacrylate). J. Vac. Sci. Technol. B Microelectron. Nanom. Struct. Process. Meas. Phenom. 2004, 22, 1711-1716. https://doi.org/10.1116/1.1763897.

Chen, Y. Nanofabrication by Electron Beam Lithography and Its Applications: A Review. Microelectron. Eng. 2015, 135, 57-72. https://doi.org/10.1016/j.mee.2015.02.042.

Manfrinato, V. R.; Camino, F. E.; Stein, A.; Zhang, L.; Lu, M.; Stach, E. A.; Black, C. T. Patterning Si at the 1 Nm Length Scale with Aberration-Corrected Electron-Beam Lithography: Tuning of Plasmonic Properties by Design. Adv. Funct. Mater. 2019, 29. https://doi.org/10.1002/adfm.201903429.

Schift, H. Nanoimprint Lithography: An Old Story in Modern Times? A Review. J. Vac. Sci. Technol. B Microelectron. Nanom. Struct. 2008, 26 (2), 458. https://doi.org/10.1116/1.2890972.

Kwon, B.; Kim, J. H. Importance of Molds for Nanoimprint Lithography: Hard, Soft, and Hybrid Molds. J. Nanosci. 2016. https://doi.org/10.1155/2016/6571297.

Oh, D. K.; Lee, T.; Ko, B.; Badloe, T.; Ok, J. G.; Rho, J. Nanoimprint Lithography for High-Throughput Fabrication of Metasurfaces. Frontiers of Optoelectronics. Higher Education Press Limited Company 2021. https://doi.org/10.1007/s12200-021-1121-8.

Ryu Cho, Y. K.; Rawlings, C. D.; Wolf, H.; Spieser, M.; Bisig, S.; Reidt, S.; Sousa, M.; Khanal, S. R.; Jacobs, T. D. B.; Knoll, A. W. Sub-10 Nanometer Feature Size in Silicon Using Thermal Scanning Probe Lithography. ACS Nano 2017, 11, 11890-11897. https://doi.org/10.1021/acsnano.7b06307.

Howell, S. T.; Grushina, A.; Holzner, F.; Brugger, J. Thermal Scanning Probe Lithography˜a Review. Microsystems Nanoeng. 2020, 6. https://doi.org/10.1038/s41378-019-0124-8.

Kaestner, M.; Rangelow, I. W. Scanning Probe Lithography on Calixarene towards Single-Digit Nanometer Fabrication. Int. J. Extrem. Manuf 2020, 2. https://doi.org/10.1088/2631-7990/aba2d8.

Spende, A.; Sobel, N.; Lukas, M.; Zierold, R.; Riedl, J. C.; Gura, L.; Schubert, I.; Moreno, J. M. M.; Nielsch, K.; Stühn, B.; Hess, C.; Trautmann, C.; Toimil-Molares, M. E. TiO₂, SiO₂, and Al2O3 Coated Nanopores and Nanotubes Produced by ALD in Etched Ion-Track Membranes for Transport Measurements. Nanotechnology 2015, 26. https://doi.org/10.1088/0957-4484/26/33/335301.

Walavalkar, S. S.; Hofmann, C. E.; Homyk, A. P.; Henry, M. D.; Atwater, H. A.; Scherer, A. Tunable Visible and Near-IR Emission from Sub-10 Nm Etched Single-Crystal Si Nanopillars. Nano Lett. 2010, 10, 4423-4428. https://doi.org/10.1021/nl102140k.

Krauss, P. R.; Chou, S. Y. Sub-10 Nm Imprint Lithography and Applications. J. Vac. Sci. Technol. B Microelectron. Nanom. Struct. Process. Meas. Phenom. 1997, 15, 2897-2904. https://doi.org/10.1116/1.589752.

Austin, M. D.; Ge, H.; Wu, W.; Li, M.; Yu, Z.; Wasserman, D.; Lyon, S. A.; Chou, S. Y. Fabrication of 5 Nm Linewidth and 14 Nm Pitch Features by Nanoimprint Lithography. Appl. Phys. Lett. 2004, 84 (26), 5299-5301. https://doi.org/10.1063/1.1766071.

Pina-Hernandez, C.; Fu, P. F.; Guo, L. J. Ultrasmall Structure Fabrication via a Facile Size Modification of Nanoimprinted Functional Silsesquioxane Features. ACS Nano 2011, 5 (2), 923-931. https://doi.org/10.1021/nn102127z.

Pi, S.; Lin, P.; Xia, Q. Fabrication of Sub-10 Nm Metal Nanowire Arrays with Sub-1 Nm Critical Dimension Control. Nanotechnology 2016, 27 (46). https://doi.org/10.1088/0957-4484/27/46/464004.

Schvartzman, M.; Wind, S. J. Robust Pattern Transfer of Nanoimprinted Features for Sub-5-Nm Fabrication. Nano Lett. 2009, 9 (10), 3629-3634. https://doi.org/10.1021/nl9018512.

Mirza, M. M.; Zhou, H.; Velha, P.; Li, X.; Docherty, K. E.; Samarelli, A.; Ternent, G.; Paul, D. J. Nanofabrication of High Aspect Ratio (050:1) Sub-10 Nm Silicon Nanowires Using Inductively Coupled Plasma Etching. J. Vac. Sci. Technol. B, Nanotechnol. Microelectron. Mater. Process. Meas. Phenom. 2012, 30. https://doi.org/10.1116/1.4755835.

Peroz, C.; Dhuey, S.; Cornet, M.; Vogler, M.; Olynick, D.; Cabrini, S. Single Digit Nanofabrication by Step-and-Repeat Nanoimprint Lithography. Nanotechnology 2012, 23, 5. https://doi.org/10.1088/0957-4484/23/1/015305.

Cheng, J. Y.; Mayes, A. M.; Ross, C. A. Nanostructure Engineering by Templated Self-Assembly of Block Copolymers. Nat. Mater. 2004, 3 (11), 823-828. https://doi.org/10.1038/nmat1211.

Stoykovich, M. P.; Kang, H.; Daoulas, K. C.; Liu, G.; Liu, C. C.; De Pablo, J. J.; Muller, M.; Nealey, P. F. Directed Self-Assembly of Block Copolymers for Nanolithography: Fabrication of Isolated Features and Essential Integrated Circuit Geometries. ACS Nano 2007, 1 (3), 168-175. https://doi.org/10.1021/nn700164p.

Hu, H.; Gopinadhan, M.; Osuji, C. O. Directed Self-Assembly of Block Copolymers: A Tutorial Review of Strategies for Enabling Nanotechnology with Soft Matter. Soft Matter. Royal Society of Chemistry Jun. 14, 2014, pp 3876-3889. https://doi.org/10.1039/c3sm52607k.

Maher, M. J.; Mori, K.; Sirard, S. M.; Dinhobl, A. M.; Bates, C. M.; Gurer, E.; Blachut, G.; Lane, A. P.; Durand, W. J.; Carlson, M. C.; Strahan, J. R.; Ellison, C. J.; Willson, C. G. Pattern Transfer of Sub-10 Nm Features via Tin-Containing Block Copolymers. ACS Macro Lett. 2016, 5, 391-395. https://doi.org/10.1021/acsmacrolett.6b00005.

Lane, A. P.; Yang, X.; Maher, M. J.; Blachut, G.; Asano, Y.; Someya, Y.; Mallavarapu, A.; Sirard, S. M.; Ellison, C. J.; Willson, C. G. Directed Self-Assembly and Pattern Transfer of Five Nanometer Block Copolymer Lamellae. ACS Nano 2017, 11, 7656-7665. https://doi.org/10.1021/acsnano.7b02698.

Pang, Y.; Jin, X.; Huang, G.; Wan, L.; Ji, S. Directed Self-Assembly of Styrene-Methyl Acrylate Block Copolymers with Sub-7 Nm Features via Thermal Annealing. Macromolecules 2019, 52, 2987-2994. https://doi.org/10.1021/acs.macromo1.9b00174.

Gusmão Cacho, M. G.; Pimenta-Barros, P.; Argoud, M.; Navarro, C.; Sakavuyi, K.; Tiron, R.; Possémé, N. Etching of Sub-10 Nm Half-Pitch High Chi Block Copolymers for Directed Self-Assembly (DSA) Application. Microelectron. Eng. 2020, 230. https://doi.org/10.1016/j.mee.2020.111369.

Chen, Y.; Xiong, S. Directed Self-Assembly of Block Copolymers for Sub-10 Nm Fabrication. International Journal of Extreme Manufacturing. IOP Publishing Ltd Sep. 1, 2020. https://doi.org/10.1088/2631-7990/aba3ae.

Park, S.-M.; Liang, X.; Harteneck, B. D.; Pick, T. E.; Hiroshiba, N.; Wu, Y.; Helms, B. A.; Olynick, D. L. Sub-10 Nm Nanofabrication via Nanoimprint Directed Self-Assembly of Block Copolymers. ACS Nano 2011, 5 (11), 8523-8531. https://doi.org/10.1021/nn201391d.

Li, J.; Zhou, C.; Chen, X.; Rincon Delgadillo, P. A.; Nealey, P. F. Orientation Control of High-χ Triblock Copolymer for Sub-10 Nm Patterning Using Fluorine-Containing Polymeric Additives. J. Micro/Nanolithography, MEMS, MOEMS 2019, 18 (3), 1. https://doi.org/10.1117/1.jmm.18.3.035501.

Ruiz, R.; Kang, H.; Detcheverry, F. A.; Dobisz, E.; Kercher, D. S.; Albrecht, T. R.; De Pablo, J. J.; Nealey, P. F. Density Multiplication and Improved Lithography by Directed Block Copolymer Assembly. Science (80-.). 2008, 321 (5891), 936-939.

Xiong, S.; Wan, L.; Ishida, Y.; Chapuis, Y. A.; Craig, G. S. W.; Ruiz, R.; Nealey, P. F. Directed Self-Assembly of Triblock Copolymer on Chemical Patterns for Sub-10-Nm Nanofabrication via Solvent Annealing. ACS Nano 2016, 10 (8), 7855-7865. https://doi.org/10.1021/acsnano.6b03667.

Ji, S.; Wan, L.; Liu, C.-C.; Nealey, P. F. Directed Self-Assembly of Block Copolymers on Chemical Patterns: A Platform for Nanofabrication. Prog. Polym. Sci. 2016, 5455, 76˜ 127. https://doi.org/10.1016/j.progpolymsci.2015.10.006.

Tseng, Y. C.; Peng, Q.; Ocola, L. E.; Elam, J. W.; Darling, S. B. Enhanced Block Copolymer Lithography Using Sequential Infiltration Synthesis. J. Phys. Chem. C 2011, 115, 17725-17729. https://doi.org/10.1021/jp205532e.

Peng, Q.; Tseng, Y. C.; Darling, S. B.; Elam, J. W. A Route to Nanoscopic Materials via Sequential Infiltration Synthesis on Block Copolymer Templates. ACS Nano 2011, 5 (6), 4600-4606. https://doi.org/10.1021/nn2003234.

Cara, E.; Murataj, I.; Milano, G.; De Leo, N.; Boarino, L.; Lupi, F. F. Recent Advances in Sequential Infiltration Synthesis (Sis) of Block Copolymers (Bcps). Nanomaterials. MDPI AG Apr. 1, 2021. https://doi.org/10.3390/nano11040994.

Kuo, C. W.; Shiu, J. Y.; Chen, P.; Somorjai, G. A. Fabrication of Size-Tunable Large-Area Periodic Silicon Nanopillar Arrays with Sub-10-Nm Resolution. Journal of Physical Chemistry B. American Chemical Society Sep. 18, 2003, pp 9950-9953. https://doi.org/10.1021/jp035468d.

Yang, S. M.; Jang, S. G.; Choi, D. G.; Kim, S.; Yu, H. K. Nanomachining by Colloidal Lithography. Small. 2006. https://doi.org/10.1002/sm11.200500390.

Zhang, J.; Li, Y.; Zhang, X.; Yang, B. Colloidal Self-Assembly Meets Nanofabrication: From Two-Dimensional Colloidal Crystals to Nanostructure Arrays. Advanced Materials. 2010. https://doi.org/10.1002/adma.201000755.

Ye, X.; Qi, L. Two-Dimensionally Patterned Nanostructures Based on Monolayer Colloidal Crystals: Controllable Fabrication, Assembly, and Applications. Nano Today. Dec. 2011, pp 608-631. https://doi.org/10.1016/j.nantod.2011.10.002.

Lotito, V.; Zambelli, T. Self-Assembly and Nanosphere Lithography for Large-Area Plasmonic Patterns on Graphene. J. Colloid Interface Sci. 2015, 447, 202-210. https://doi.org/10.1016/j.jcis.2014.11.007.

Ai, B.; Mohwald, H.; Wang, D.; Zhang, G. Advanced Colloidal Lithography Beyond Surface Patterning. Advanced Materials Interfaces. 2017. https://doi.org/10.1002/admi.201600271.

Liu, J.; Zhang, X.; Li, W.; Jiang, C.; Wang, Z.; Xiao, X. Recent Progress in Periodic Patterning Fabricated by Self-Assembly of Colloidal Spheres for Optical Applications. Science China Materials. Science China Press Aug. 1, 2020, pp 1418-1437. https://doi.org/10.1007/s40843-020-1284-8.

Rey, M.; Wendisch, F. J.; Aaron Goerlitzer, E. S.; Julia Tang, J. S.; Bader, R. S.; Bourret, G. R.; Vogel, N. Anisotropic Silicon Nanowire Arrays Fabricated by Colloidal Lithography. Nanoscale Adv. 2021, 3 (12), 3634-3642. https://doi.org/10.1039/d1na00259g.

Hogg, C. R.; Majetich, S. A.; Bain, J. A. Investigating Pattern Transfer in the Small-Gap Regime Using Electron-Beam Stabilized Nanoparticle Array Etch Masks. IEEE Trans. Magn. 2010, 46 (6), 2307-2310. https://doi.org/10.1109/TMAG.2010.2040145.

Wen, T.; Booth, R. A.; Majetich, S. A. Ten-Nanometer Dense Hole Arrays Generated by Nanoparticle Lithography. Nano Lett. 2012, 12 (11), 5873-5878. https://doi.org/10.1021/nl3032372.

Hogg, C. R.; Picard, Y. N.; Narasimhan, A.; Bain, J. A.; Majetich, S. A. Pattern Transfer with Stabilized Nanoparticle Etch Masks. Nanotechnology 2013, 24. https://doi.org/10.1088/0957-4484/24/8/085303.

What is claimed:

1. A patterning method, comprising:
disposing a nanoparticle composition on a support material,
the nanoparticle composition optionally comprising nanocrystals, the disposing being performed such that the nanoparticle composition defines a patterned region having an average inter-nanoparticle distance of less than about 5 nm; and
selectively etching the support material so as to give rise to in the support material a plurality of arrayed structures substantially in register with the patterned region of the nanoparticle composition.

2. The method of claim 1, wherein the nanoparticle composition comprises nanoparticles that include one or more rare earth elements.

3. The method of claim 1, wherein the nanoparticles comprise rare earth fluoride compounds.

4. The method of claim 1, wherein the nanoparticles comprise ligands present thereon.

5. The method of claim 4, wherein the ligands are dendritic.

6. The method of claim 1, wherein the nanoparticles are characterized as non-spherical.

7. The method of claim 6, wherein the nanoparticles are characterized as rhombic.

8. The method of claim 1, wherein the nanoparticles comprise GdF₃.

9. The patterning method of claim 1, wherein the nanoparticle composition self-assembles so as to form the patterned region.

10. The method of claim 1, wherein the support material is disposed on a substrate, and further comprising etching the substrate so as to give rise to in the substrate a plurality of arrayed structures substantially in register with the patterned region of the nanoparticle composition.

11. An article, comprising an article made according to claim 1.

12. A workpiece, comprising:
an etchable support material; and
a nanoparticle composition,
the nanoparticle composition optionally comprising nanocrystals,
the nanoparticle composition being disposed on the etchable support material as a monolayer,
the nanoparticle composition defining a patterned region having an average inter-nanoparticle distance of less than about 5 nm, and
nanoparticles of the nanoparticle composition having ligands disposed thereon.

13. The workpiece of claim 12, wherein the etchable support material defines therein a plurality of arrayed structures substantially in register with the patterned region of the nanoparticle composition.

14. The workpiece of claim 12, further comprising an etchable substrate, the etchable support material being disposed on the etchable substrate.

15. The workpiece of claim 14, wherein the etchable substrate defines therein a plurality of arrayed structures substantially in register with the patterned region of the nanoparticle composition.

16. An article, comprising:
a substrate,
the substrate having formed therein a plurality of structures arranged arrayed periodically,
the structures defining an average inter-structure spacing of less than about 5 nm.

17. The article of claim 16, wherein the substrate comprises silicon, SiO₂, SiNₓ, a semiconductor, a magnetic material, a dielectric material, an amorphous material, a quantum material, or any combination thereof.

18. The article of claim 16, wherein the structures are characterized as pillars or mesas.

19. The article of claim 16, wherein a structure defines a cross-sectional dimension in the range of from about 1 to about 100 nm.

20. The article of claim 16, wherein the structures are polygonal in cross-section.
